(19) United States
(12) Patent Application Publication
(10) Pub. No.: US 2026/0362807 A1
(43) Pub. Date: Nov. 12, 2026

(54) ELECTRONIC DEVICE

(71) Applicant: InnoLux Corporation, Miao-Li County (TW)

(72) Inventors: Chandra LIUS, Miao-Li County (TW); Kuan-Feng Lee, Miao-Li County (TW)

(73) Assignee: InnoLux Corporation, Miao-Li County (TW)

(21) Appl. No.: 19/578,851

(22) Filed: Mar. 25, 2026

(30) Foreign Application Priority Data
May 6, 2025 (CN) 202510572618.3

(51) Int. Cl. H10D 86/40; H10D 86/60

(52) U.S. Cl. CPC H10D 86/441; H10D 86/451; H10D 86/60

(57) ABSTRACT

An electronic device is provided. The electronic device comprises a substrate, a first transistor, and an electronic unit. The first transistor is disposed on the substrate. The electronic unit is electrically connected to the first transistor. The first transistor comprises a first conductive element, a first control element, a first semiconductor, and a second conductive element. The first conductive element is disposed on the substrate. The first control element is disposed on the first conductive element. The first semiconductor is disposed between the first conductive element and the first control element. The second conductive element is disposed on the first control element and is electrically connected to the first semiconductor and the first conductive element. In a top view of the electronic device, the first control element is overlapped with the second conductive element.

### BACKGROUND OF THE DISCLOSURE

### 1. Field of the Disclosure

The present disclosure relates to an electronic device, and more particularly, to an electronic device comprising a transistor having a conductive element.

### 2. Description of the Prior Art

With the advancement of technology, electronic devices have become indispensable items in modern life. Among them, transistors are widely used in various electronic devices as driving elements. However, in large-sized electronic devices, the driving capability of transistors needs to be further improved. Therefore, how to improve the performance of transistors through structural design is still one of the important issues in this field.

### SUMMARY OF THE DISCLOSURE

An object of the present disclosure is to provide an electronic device, in which a stacked design of a first transistor can adjust a resistance of a local region of a first semiconductor, and a first conductive element and a second conductive element can serve as barrier layers to reduce the diffusion of hydrogen ions and oxygen ions into a channel region, thereby improving the driving capability and stability of the first transistor. An embodiment of the present disclosure provides an electronic device, which comprises a substrate, a first transistor, and an electronic unit. The first transistor is disposed on the substrate. The electronic unit is electrically connected to the first transistor. The first transistor comprises a first conductive element, a first control element, a first semiconductor, and a second conductive element. The first conductive element is disposed on the substrate. The first control element is disposed on the first conductive element. The first semiconductor is disposed between the first conductive element and the first control element. The second conductive element is disposed on the first control element and electrically connected to the first semiconductor and the first conductive element. In a top view of the electronic device, the first control element is overlapped with the second conductive element and the first semiconductor.

### BRIEF DESCRIPTION OF THE DRAWINGS

FIG. 1 is a schematic structural diagram of an electronic device according to an embodiment of the present disclosure.

FIG. 2A is an equivalent circuit diagram of a transistor and an electronic unit of an electronic device according to an embodiment of the present disclosure.

FIG. 2B is a schematic top view of a portion of an electronic device according to an embodiment of the present disclosure.

FIG. 3A is a schematic top view of a portion of an electronic device according to a first embodiment of the present disclosure.

FIG. 3B is a schematic cross-sectional view of a portion of the electronic device according to the first embodiment of the present disclosure.

FIG. 4 is a partially enlarged schematic cross-sectional view of the electronic device shown in FIG. 3A.

FIG. 5A is a schematic cross-sectional view of a portion of an electronic device according to a second embodiment of the present disclosure.

FIG. 5B is a schematic cross-sectional view of a portion of an electronic device according to a third embodiment of the present disclosure.

FIGS. 6A-6F are schematic top views of a portion of an electronic device according to some embodiments of the third embodiment of the present disclosure.

FIG. 7 is a schematic top view of a first semiconductor and a first control element according to an embodiment of the present disclosure.

FIG. 8A is a schematic top view of a first semiconductor and a first control element according to another embodiment of the present disclosure.

FIGS. 8B-8D are schematic top views of a first semiconductor and a first control element according to yet other embodiments of the present disclosure.

FIG. 9 is a voltage-current characteristic curve diagram of a first transistor of an embodiment of the present disclosure and a comparative example.

FIG. 10 is a schematic cross-sectional view of a portion of an electronic device according to a fourth embodiment of the present disclosure.

FIG. 11A is a schematic cross-sectional view of a portion of an electronic device according to a fifth embodiment of the present disclosure.

FIG. 11B is a schematic top view of a portion of the electronic device according to the fifth embodiment of the present disclosure.

FIG. 12 is a schematic cross-sectional view of a portion of a variation of the electronic device according to the fifth embodiment of the present disclosure.

FIG. 13 is a schematic top view of a portion of another variation of the electronic device according to the fifth embodiment of the present disclosure.

FIG. 14 is a schematic cross-sectional view of a portion of an electronic device according to a sixth embodiment of the present disclosure.

FIG. 15 is a schematic cross-sectional view of a portion of an electronic device according to a seventh embodiment of the present disclosure.

FIG. 16A is a schematic cross-sectional view of an electronic device having a third transistor according to an embodiment of the present disclosure.

FIG. 16B is a schematic cross-sectional view of an electronic device having a third transistor according to another embodiment of the present disclosure.

FIG. 16C is a schematic cross-sectional view of an electronic device having a third transistor according to yet another embodiment of the present disclosure.

### DETAILED DESCRIPTION

The content of the present disclosure is described in detail below with reference to specific embodiments and the accompanying drawings. It should be noted that, for the ease of understanding for the reader and the conciseness of the drawings, many drawings in the present disclosure only depict a part of a device or structure, and the specific elements in the drawings are not drawn to actual scale. In addition, the number and size of each element in the drawings are for illustrative purposes only and are not intended to limit the scope of the present disclosure.

Throughout the specification and claims of the present disclosure, certain terms are used to refer to specific elements. Those of ordinary skill in the art should understand that manufacturers of electronic devices may refer to the same element by different names. The present disclosure is not intended to distinguish between elements that have the same function but different names. In the following specification and claims, words such as "comprising" and "including" are open-ended terms and therefore should be interpreted as "comprising but not limited to...". When the terms "comprising," "including," and/or "having" are used in the specification of the present disclosure, they specify the presence of the stated features, regions, steps, operations, and/or elements, but do not preclude the presence or addition of one or more other features, regions, steps, operations, elements, and/or combinations thereof.

When an element or a layer is referred to as being "on" or "connected to" another element or layer, it can be directly on or directly connected to the other element or layer, or intervening elements or layers may be present. In contrast, when an element is referred to as being "directly on" or "directly connected to" another element or layer, there are no intervening elements or layers present.

The directional terms mentioned in the present disclosure, such as "up," "down," "front," "back," "left," "right," etc., are only for referencing the directions in the drawings. Therefore, the directional terms used are for illustration and not for limiting the present disclosure.

The terms "approximately," "equal to," "equivalent to" or "the same," "substantially," or "generally" are generally interpreted to be within 20% of a given value or range, or within 10%, 5%, 3%, 2%, 1%, or 0.5% of a given value or range.

The ordinal numbers such as "first," "second," etc., used in the specification and claims of the present disclosure are used to modify elements, and they do not in themselves imply or represent that the element(s) have any previous ordinal number, nor do they represent the order of one element relative to another, or the order in a manufacturing method. The use of these ordinal numbers is only to clearly distinguish an element with a certain name from another element with the same name. The claims and the specification may not use the same terms. Accordingly, a first element in the specification may be a second element in the claims.

The electronic device described in the present disclosure can be applied to a display device, a light-emitting device, a backlight device, an antenna device, a sensing device, or a tiling device, but is not limited thereto. The electronic device can be a bendable or flexible electronic device. The display device can be a non-self-emissive display device or a self-emissive display device. The antenna device can be a liquid crystal type antenna device or a non-liquid crystal type antenna device. The sensing device can be a sensing device for sensing capacitance, light, heat, or ultrasound, but is not limited thereto. The electronic device can comprise electronic elements such as passive elements and active elements, for example, capacitors, resistors, inductors, diodes, transistors, etc. The diode can comprise a light-emitting diode or a photodiode. The light-emitting diode can, for example, comprise an organic light-emitting diode (OLED), a mini-LED, a micro-LED, or a quantum dot LED, but is not limited thereto. The tiling device can be, for example, a display tiling device or an antenna tiling device, but is not limited thereto. It should be noted that the electronic device can be any arrangement or combination of the foregoing, but is not limited thereto.

It should be understood that features from several different embodiments can be replaced, reorganized, and mixed to complete other embodiments without departing from the spirit of the present disclosure.

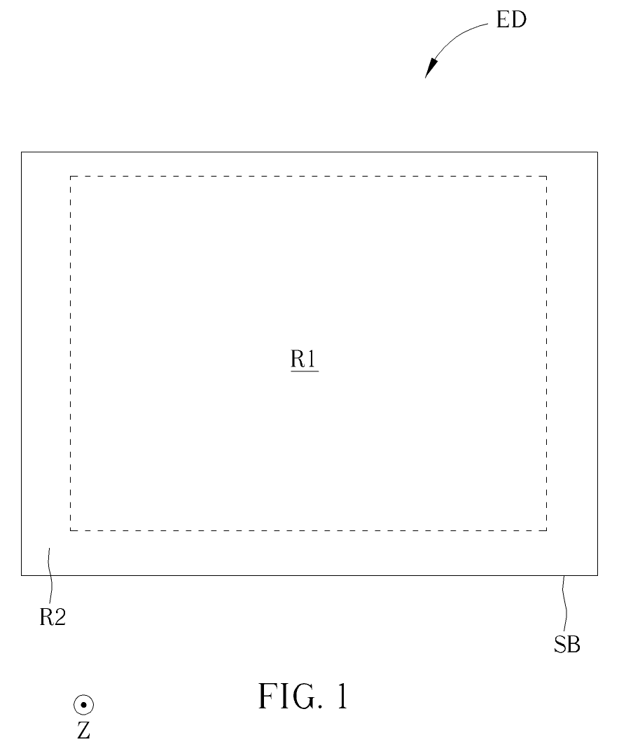

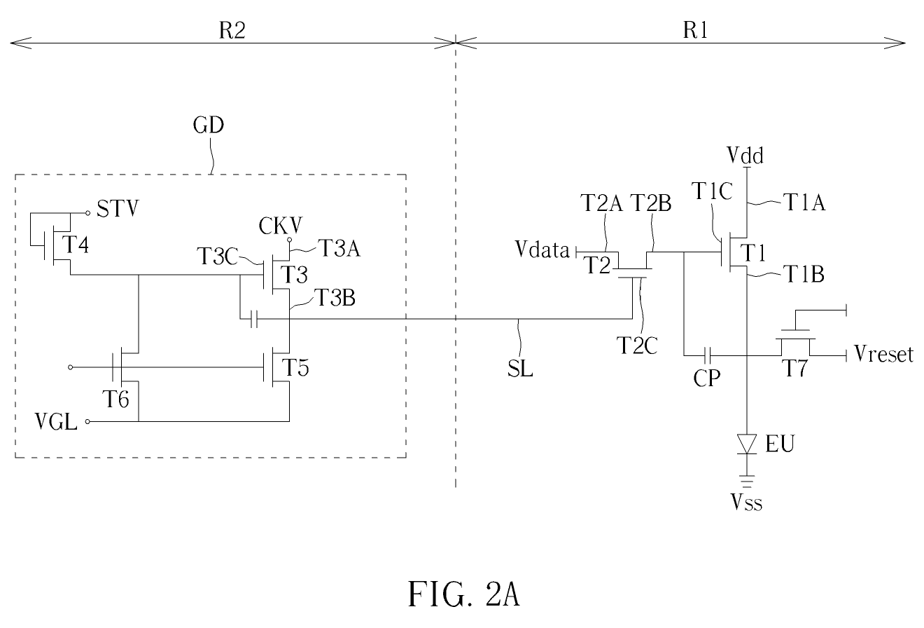

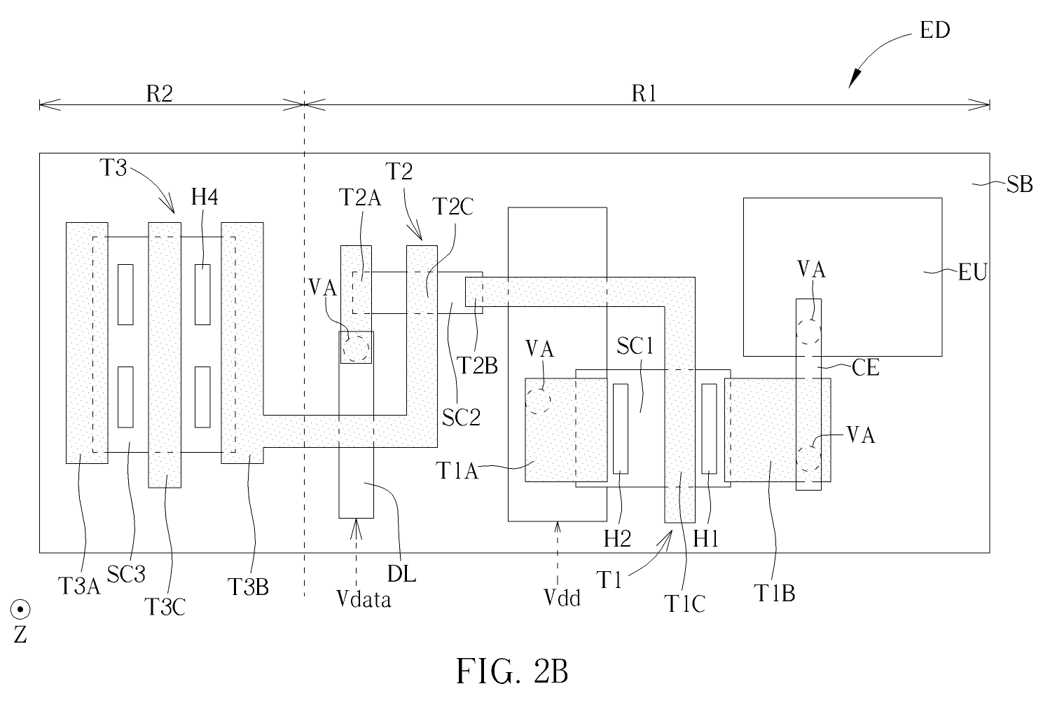

Please refer to FIGS. 1, 2A, and 2B. FIG. 1 is a schematic structural diagram of an electronic device according to an embodiment of the present disclosure. FIG. 2A is an equivalent circuit diagram of a transistor and an electronic unit of an electronic device according to an embodiment of the present disclosure. FIG. 2B is a schematic top view of a portion of an electronic device according to an embodiment of the present disclosure. For the conciseness of the drawings, FIG. 2B only shows a top view of some elements of the electronic device ED corresponding to FIG. 2A. As shown in FIGS. 1, 2A, and 2B, the electronic device ED has a working area R1 and a peripheral area R2. The peripheral area R2 is adjacent to the working area R1. For example, the peripheral area R2 can be located around the working area R1, but is not limited thereto. The electronic device ED comprises a substrate SB, a first transistor T1, and an electronic unit EU. The first transistor T1 is disposed on the substrate SB. The electronic unit EU is electrically connected to the first transistor T1 and can be disposed on the substrate SB. The first transistor T1 and the electronic unit EU can be disposed in the working area R1. The working area R1 can be an operating area or an active area of the electronic device ED. Depending on the actual application of the electronic device ED, it can be, for example (but not limited to), a display area, a light-emitting area, a sensing area, or a touch-sensitive area. For example, when the working area R1 can provide a display function or a light-emitting function, the electronic device ED can be a display device and/or a light-emitting device. When the working area R1 can provide a touch-sensitive function or a sensing function, the electronic device ED can be a touch-sensitive device, a touch-sensitive display device, and/or a sensing device, but is not limited to the above. The substrate SB can comprise a rigid material or a flexible material, for example, comprising glass, quartz, sapphire, ceramic, polyimide (PI), polycarbonate (PC), polyethylene terephthalate (PET), other suitable materials, or a combination of the above, but is not limited thereto.

The first transistor T1 may comprise a first control element T1C, a first semiconductor SC1, a first terminal T1A, and a second terminal T1B. The first control element T1C may be a gate and, in a direction Z, is overlapped with the first semiconductor SC1. In FIG. 2B, the first terminal T1A and the second terminal T1B may be a first electrode and a second electrode of the first transistor T1, respectively, and are electrically connected to opposite ends of the first semiconductor SC1. One of the first terminal T1A (also referred to as the first electrode) and the second terminal T1B (also referred to as the second electrode) may be a source and the other may be a drain. The first transistor T1 may serve as a driving element, but is not limited to the above. In the present disclosure, the direction Z may be a normal direction of the substrate SB and may be parallel to a top-view direction of the electronic device ED. The first terminal T1A of the first transistor T1 may receive a working signal Vdd, and the second terminal T1B of the first transistor T1 may be electrically connected to the electronic unit EU and may output a driving signal to the electronic unit EU, while another terminal of the electronic unit EU may be electrically connected to a ground voltage Vss. For example, as shown in FIG. 2B, the second terminal T1B may be first electrically connected to a conductive element CE through a via VA, and then the conductive element CE is electrically connected to the electronic unit EU through another via VA. In an embodiment, an insulating layer is between the second terminal T1B and the conductive element CE, and the second terminal T1B can be electrically connected to the conductive element CE through the via VA in the insulating layer.

The electronic device ED may further comprise a second transistor T2 and a gate signal driving circuit GD disposed on the substrate SB, wherein the second transistor T2 may be disposed in the working area R1, and the gate signal driving circuit GD may be disposed in the peripheral area R2. The second transistor T2 may comprise a second control element T2C, a second semiconductor SC2, a first terminal T2A, and a second terminal T2B. The second control element T2C may be a gate and, in the direction Z, is overlapped with the second semiconductor SC2. In FIG. 2B, the first terminal T2A and the second terminal T2B of the second transistor T2 may be a first electrode and a second electrode of the second transistor T2, respectively, and are electrically connected to opposite ends of the second semiconductor SC2. One of the first terminal T2A (also referred to as the first electrode) and the second terminal T2B (also referred to as the second electrode) may be a source and the other may be a drain. The second transistor T2 may serve as a switching element. The first terminal T2A of the second transistor T2 may be electrically connected to a data line DL through a via VA to receive a data signal Vdata. The second terminal T2B of the second transistor T2 may be electrically connected to the first control element T1C of the first transistor T1. The gate signal driving circuit GD may be electrically connected to the second control element T2C of the second transistor T2. The gate signal driving circuit GD may comprise a plurality of transistors, for example, it may comprise a third transistor T3, a fourth transistor T4, a fifth transistor T5, and a sixth transistor T6 as shown in FIG. 2A, but is not limited thereto. The third transistor T3 may comprise a third control element T3C, a third semiconductor SC3, a first terminal T3A, and a second terminal T3B. The third control element T3C may be a gate and, in the direction Z, is overlapped with the third semiconductor SC3. In FIG. 2B, the first terminal T3A and the second terminal T3B of the third transistor T3 may be a first electrode and a second electrode of the third transistor T3, respectively, and are electrically connected to opposite ends of the third semiconductor SC3. One of the first terminal T3A (also referred to as the first electrode) and the second terminal T3B (also referred to as the second electrode) may be a source and the other may be a drain. The second terminal T3B of the third transistor T3 may be electrically connected to the second control element T2C of the second transistor T2.

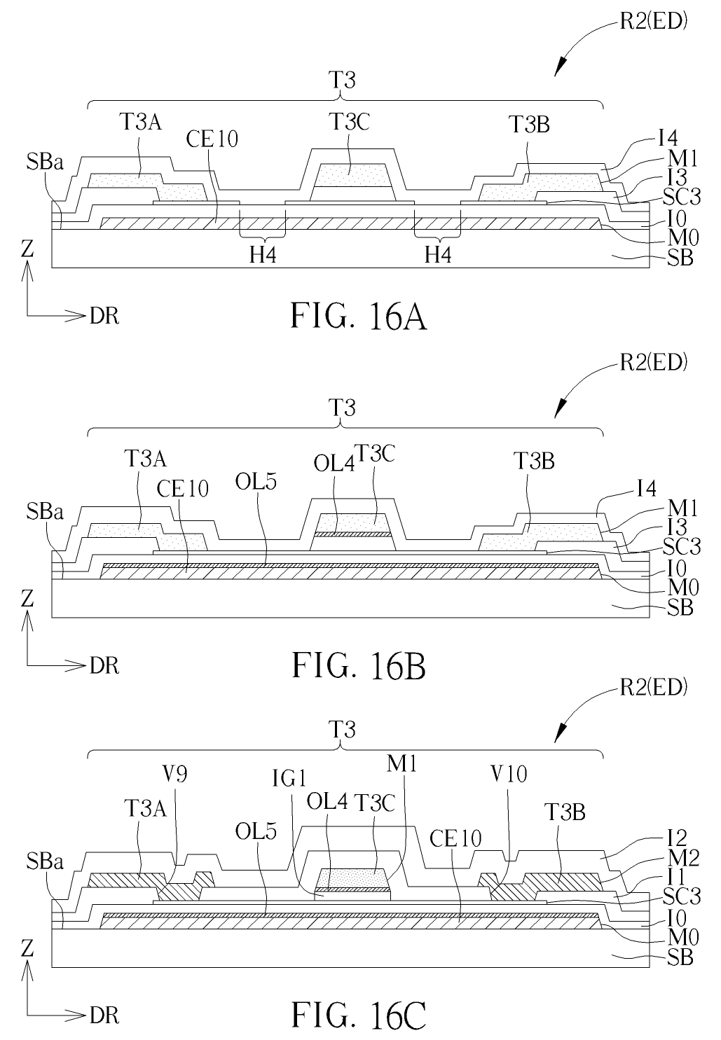

According to the embodiment shown in FIG. 2A, the fourth transistor T4 of the gate signal driving circuit GD may receive a start signal STV and may be electrically connected to the third transistor T3. The fifth transistor T5 and the sixth transistor T6 may receive a low voltage VGL. The first terminal T3A of the third transistor T3 may receive a clock signal CKV, and the second terminal T3B of the third transistor T3 may be electrically connected to the second control element T2C of the second transistor T2 through a signal line SL. The electronic device ED may further comprise a seventh transistor T7, disposed in the working area R1. The seventh transistor T7 may receive a reset signal Vreset and may be electrically connected to the second terminal T1B of the first transistor T1. The first transistor T1, the second transistor T2, the third transistor T3, the fourth transistor T4, the fifth transistor T5, the sixth transistor T6, and the seventh transistor T7 may be, for example, thin film transistors (TFTs) and each comprises a semiconductor. The semiconductor may be a low-temperature poly-silicon (LTPS) semiconductor or a metal oxide semiconductor. Different transistors may have semiconductors of the same material, or some transistors may have LTPS semiconductors while other transistors have metal oxide semiconductors, but the present disclosure is not limited thereto. The electronic unit EU may be, for example, a light-emitting element (such as the light-emitting diode shown in FIG. 2A), but is not limited thereto. It should be noted that the circuit and structure of the electronic device ED shown in FIGS. 2A and 2B are only examples, and the present disclosure is not limited thereto. The detailed structure of the electronic device ED comprising the first transistor T1 will be mainly described below. The detailed structures of the second transistor T2 and the third transistor T3 will be described later in conjunction with FIGS. 16A-16C.

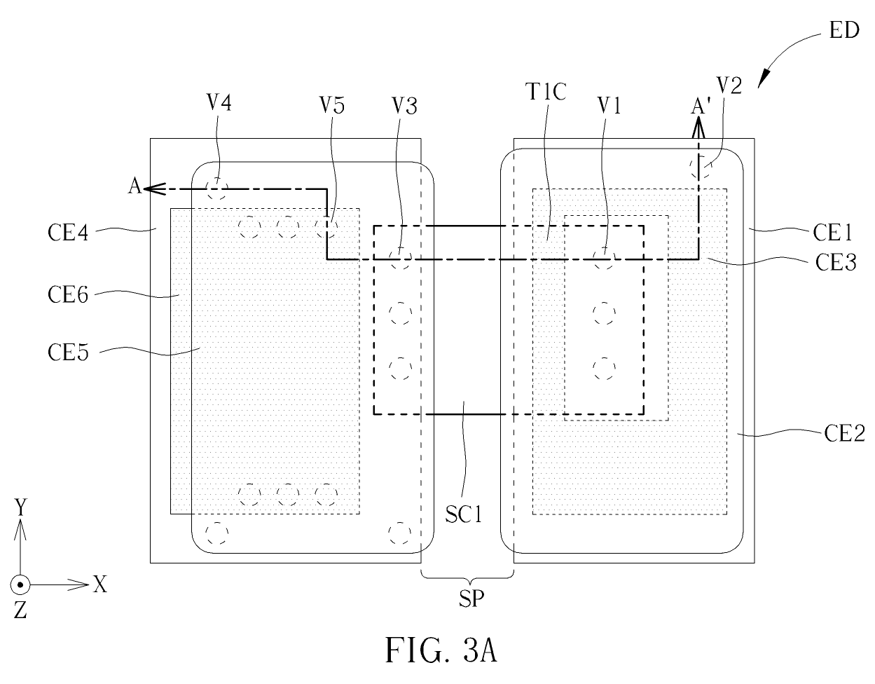

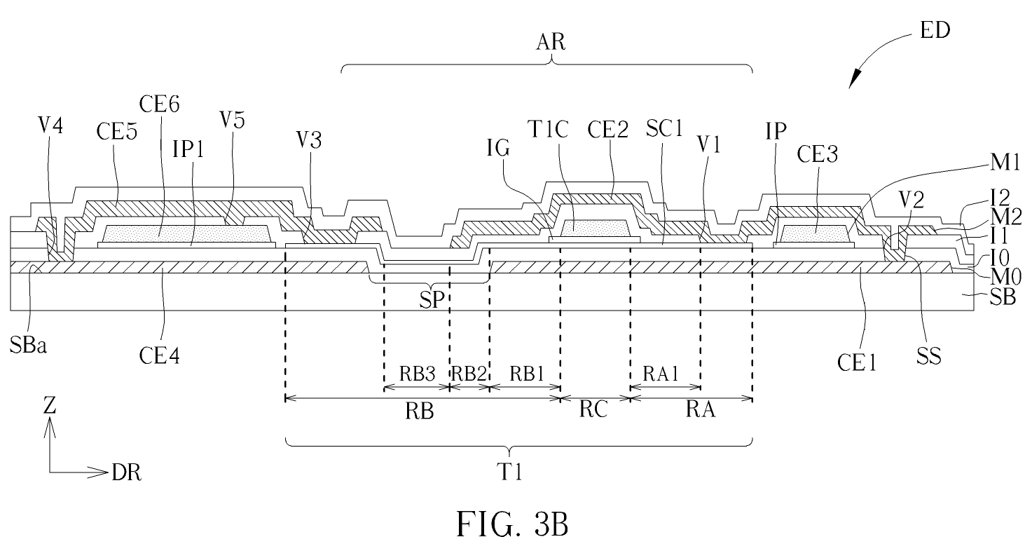

Please refer to FIGS. 3A and 3B. FIG. 3A is a schematic top view of a portion of an electronic device according to a first embodiment of the present disclosure. FIG. 3B is a schematic cross-sectional view of a portion of the electronic device according to the first embodiment of the present disclosure. For the conciseness of the drawings, FIG. 3A only shows a top view of some elements of the electronic device ED shown in FIG. 3B. The partial cross-sectional structure of the electronic device ED corresponding to the section line A-A' in FIG. 3A can be referred to in FIG. 3B. According to the electronic device ED of the first embodiment shown in FIGS. 3A and 3B, the first transistor T1 is disposed on the substrate SB, and the first transistor T1 comprises a first conductive element CE1, a first control element T1C, a first semiconductor SC1, and a second conductive element CE2. The first conductive element CE1 is disposed on the substrate SB, and the first control element T1C is disposed on the first conductive element CE1. In the direction Z, the first semiconductor SC1 is disposed between the first conductive element CE1 and the first control element T1C. The direction Z may be a normal direction of the substrate SB and may be parallel to a top-view direction of the electronic device ED, and the direction Z may be perpendicular to an upper surface SBa of the substrate SB or its opposite lower surface. The second conductive element CE2 is disposed on the first control element T1C and is electrically connected to the first semiconductor SC1 and the first conductive element CE1. As shown in FIG. 3A, in a top view of the electronic device ED, or when viewing the electronic device ED from a direction opposite to the direction Z, in the direction Z, the first control element T1C is overlapped with the second conductive element CE2 and the first semiconductor SC1. The first control element T1C can serve as a gate of the first transistor T1, and the second conductive element CE2 can serve as a drain of the first transistor T1, for example, it can serve as the second terminal T1B (or referred to as the second electrode) shown in FIG. 2A, which can be used to output signals to the electronic unit EU.

As shown in FIG. 3B, the electronic device ED may, for example, comprise a conductive layer M0 forming the first conductive element CE1, an insulating layer I0, the first semiconductor SC1, a conductive layer M1 forming the first control element T1C, an insulating layer I1, a conductive layer M2 forming the second conductive element CE2, and an insulating layer I2, which are sequentially disposed on the upper surface SBa of the substrate SB along the direction Z. The electronic device ED may further comprise an insulating layer IG (which may be referred to as a first insulating layer), disposed between the first control element T1C and the first semiconductor SC1, to serve as a gate insulating layer. The second conductive element CE2 may be electrically connected to and directly contact the first semiconductor SC1 through a via V1 in the insulating layer I1, and the second conductive element CE2 may also be electrically connected to and directly contact the first conductive element CE1 through a via V2 in the insulating layer I1 and the insulating layer I0. In an embodiment, the conductive layer M0, the insulating layer I0, the conductive layer M1, the insulating layer I1, the conductive layer M2, and the insulating layer I2 may be single-layer structures or multi-layer structures, and the present disclosure is not limited thereto. In an embodiment, the via V2 may be formed through a single exposure and development process, therefore, the side SS of the via V2 will be connected to each other at the interface between the insulating layer I0 and the insulating layer I1. In another embodiment, the via V2 may be formed through at least two exposure and development processes, therefore, the side SS of the via V2 will be disconnected at the interface between the insulating layer I0 and the insulating layer I1. In other words, the via V2 will comprise a first part corresponding to the insulating layer I0 and a second part corresponding to the insulating layer I1, and a bottom length of the first part will be smaller than a bottom length of the second part, but is not limited thereto.

In some embodiments, the electronic device ED may further comprise a third conductive element CE3. In the cross-section of the electronic device ED as shown in FIG. 3B, the third conductive element CE3 may be disposed between the second conductive element CE2 and the first conductive element CE1, wherein the third conductive element CE3 and the first control element T1C may be formed from the same layer (i.e., the conductive layer M1). In the direction Z, the first semiconductor SC1 is not disposed between the third conductive element CE3 and the substrate SB. A capacitor (for example, the capacitor CP shown in FIG. 2A, which is electrically connected to the first transistor T1 and the electronic unit EU) may be formed between the third conductive element CE3 and the first conductive element CE1 and the second conductive element CE2, but is not limited thereto. In some embodiments, an insulating portion IP may also be disposed between the third conductive element CE3 and the insulating layer I0, but is not limited thereto.

As shown in FIGS. 3A and 3B, the electronic device ED may further comprise a fourth conductive element CE4 and a fifth conductive element CE5. The fourth conductive element CE4 is disposed on the substrate SB. In a direction X as shown in FIG. 3A or in a direction DR (cross-sectional direction) as shown in FIG. 3B, the fourth conductive element CE4 and the first conductive element CE1 may be spaced by a gap SP. In the top view shown in FIG. 3A, the direction X may be perpendicular to a direction Y and the direction Z, the direction Y may be parallel to an extending direction of the first control element T1C, and the direction X and the direction Y may be parallel to the upper surface SBa (or the lower surface) of the substrate SB. In the cross-sectional view shown in FIG. 3B, the direction DR may be perpendicular to the direction Z and parallel to the upper surface SBa (or the lower surface) of the substrate SB. The fourth conductive element CE4 and the first conductive element CE1 may be formed from the same layer (i.e., the conductive layer M0). In the direction Z, a part of the first semiconductor SC1 may be disposed between the first conductive element CE1 and the second conductive element CE2 and be overlapped with the first conductive element CE1 and the second conductive element CE2. Another part of the first semiconductor SC1 may be disposed between the fourth conductive element CE4 and the fifth conductive element CE5 and be overlapped with the fourth conductive element CE4 and the fifth conductive element CE5. The fifth conductive element CE5 may be electrically connected to the first semiconductor SC1 and the fourth conductive element CE4. The fifth conductive element CE5 may serve as a source of the first transistor T1, for example, it may serve as the first terminal T1A (or referred to as the first electrode) shown in FIG. 2A, which may be used to receive the working signal Vdd. The fifth conductive element CE5 and the second conductive element CE2 may be formed from the same layer (i.e., the conductive layer M2). As shown in FIG. 3B, the fifth conductive element CE5 may be electrically connected to the first semiconductor SC1 through a via V3 in the insulating layer I1, and the fifth conductive element CE5 may also be electrically connected to the fourth conductive element CE4 through a via V4 in the insulating layer I1 and the insulating layer I0. In some embodiments, the electronic device ED may further comprise a sixth conductive element CE6. In the direction Z, the sixth conductive element CE6 may be disposed between the fourth conductive element CE4 and the fifth conductive element CE5, and the fifth conductive element CE5 may be electrically connected to the sixth conductive element CE6. For example, the fifth conductive element CE5 may be electrically connected to the sixth conductive element CE6 through a via V5 in the insulating layer I1, but is not limited thereto. In some embodiments, the fourth conductive element CE4 and/or the fifth conductive element CE5 may also be electrically connected to other traces in the electronic device ED, and they may serve as a common electrode, for example, but are not limited thereto. In some embodiments, an insulating portion IP1 may also be disposed between the sixth conductive element CE6 and the insulating layer I0. The insulating portion IP1, the insulating portion IP, and the insulating layer IG may be formed from the same layer. For example, the insulating portion IP1, the insulating portion IP, and the insulating layer IG may be formed through the same process, but is not limited thereto. In other embodiments, the insulating portion IP1 and the insulating portion IP may not be disposed, that is, the insulating portion IP1 and the insulating portion IP are optional.

As shown in FIG. 3B, the first semiconductor SC1 can be divided into a first region RA, a second region RB, and a channel region RC. In the direction Z, the channel region RC is overlapped with the first control element T1C and the insulating layer IG. The first region RA and the second region RB are located at opposite ends of the channel region RC. When the first semiconductor SC1 is a low-temperature poly-silicon semiconductor, the first region RA and the second region RB can be ion-doped regions. The second conductive element CE2 can be electrically connected to and directly contact the first region RA through the via V1. The fifth conductive element CE5 can be electrically connected to and directly contact the second region RB through the via V3. The first region RA can comprise a first sub-region RA1. In the direction Z, the first sub-region RA1 is overlapped with the first conductive element CE1 and the second conductive element CE2 and is not overlapped with the via V1. The second region RB can comprise a first sub-region RB1, a second sub-region RB2, and a third sub-region RB3. In the direction Z, the first sub-region RB1 is overlapped with the first conductive element CE1 and the second conductive element CE2 but is not overlapped with the gap SP. In the direction Z, the second sub-region RB2 is overlapped with the second conductive element CE2 and is not overlapped with the first conductive element CE1, that is, the second sub-region RB2 can be overlapped with a part of the gap SP, or the second sub-region RB2 can refer to the part of the first semiconductor layer SC1 corresponding to the second conductive element CE2 that is overlapped with the gap SP. In the direction Z, the third sub-region RB3 is not overlapped with the first conductive element CE1, the second conductive element CE2, the fourth conductive element CE4, and the fifth conductive element CE5, but can be overlapped with the gap SP.

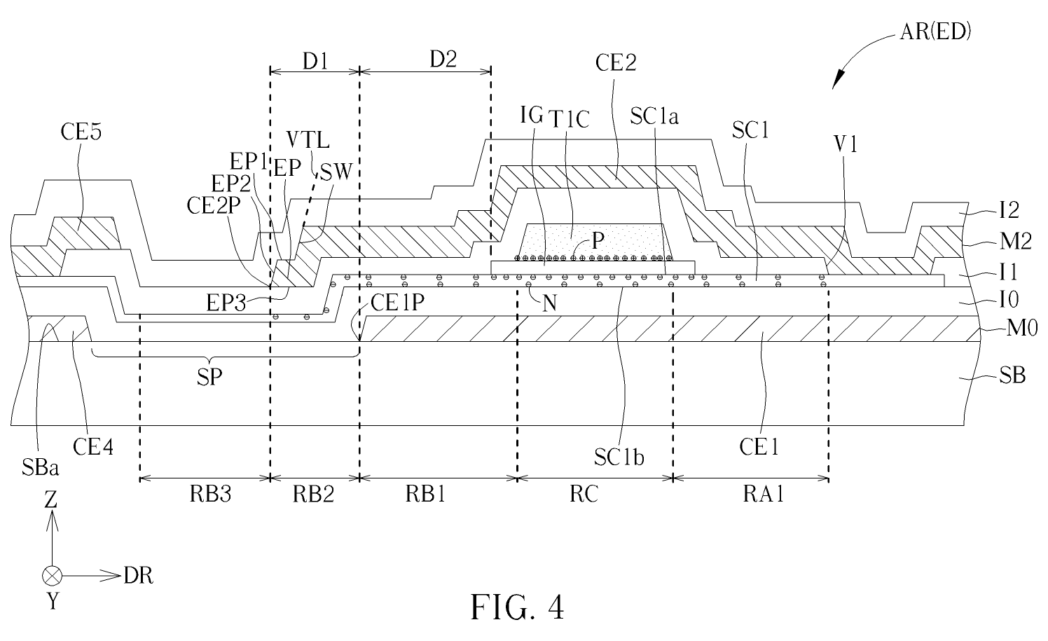

When the first transistor T1 receives a voltage signal, a potential field can be generated between the first conductive element CE1 and the second conductive element CE2, thereby reducing the resistance of a local region of the first semiconductor SC1. Specifically, please refer to FIG. 4, which is a partially enlarged schematic cross-sectional view of the electronic device shown in FIG. 3B. The partially enlarged cross-sectional structure shown in FIG. 4 corresponds to the region AR of the electronic device ED shown in FIG. 3B. As shown in FIG. 4, when the first control element T1C (i.e., the gate) and the second conductive element CE2 (i.e., the drain) of the first transistor T1 receive signals, a lower surface of the first control element T1C may have more positive charges P and a potential field may be generated between the first conductive element CE1 and the second conductive element CE2. At this time, an upper interface SC1a and a lower interface SC1b of the first semiconductor SC1 may have different characteristics in different regions. The potential of the first control element T1C is higher than the potentials of the first conductive element CE1 and the second conductive element CE2. Specifically, a conductive channel may be formed at the upper interface SC1a and the lower interface SC1b corresponding to the channel region RC and have negative charges N, and an electron concentration at the upper interface SC1a corresponding to the channel region RC is greater than an electron concentration at the lower interface SC1b corresponding to the channel region RC; electrons in the first sub-region RA1 of the first region RA and the first sub-region RB1 of the second region RB can be activated to form conductive channels at their upper and lower interfaces and have negative charges N, and an electron concentration at the upper interface (or lower interface) of the first sub-region RA1 and the first sub-region RB1 is smaller than the electron concentration at the upper interface of the channel region RC; electrons in the second sub-region RB2 of the second region RB can be activated to form a channel at its upper interface and have negative charges N, and an electron concentration at the upper interface of the second sub-region RB2 is smaller than the electron concentration at the upper interface of the channel region RC; and the third sub-region RB3 of the second region RB does not form a channel. According to the above, the potential field generated between the first conductive element CE1 and the second conductive element CE2 can activate the electrons in the first sub-region RA1 of the first region RA and the first sub-region RB1 and the second sub-region RB2 of the second region RB, thereby reducing the resistance of these regions and improving the on-state conductivity. In addition, during the manufacturing process of the electronic device ED, for example, during a thermal process, the first conductive element CE1 and/or the second conductive element CE2 can serve as a barrier layer to reduce the probability of hydrogen ions and/or oxygen ions from adjacent film layers (such as the substrate SB and the insulating layer I2) diffusing into the channel region RC of the first transistor T1.

As shown in FIG. 4, the second conductive element CE2 has an end portion EP corresponding to the gap SP between the first conductive element CE1 and the fourth conductive element CE4, and a shape of the end portion EP may be step-shaped. The second conductive element CE2 has an endpoint CE2P corresponding to the gap SP. A part of the insulating layer I1 corresponding to the gap SP and disposed between the first semiconductor SC1 and the second conductive element CE2 has a sidewall SW that is not parallel to the upper surface SBa of the substrate SB. An extension line VTL can be drawn along this sidewall SW. The part of the second conductive element CE2 between the extension line VTL and the endpoint CE2P can be defined as the end portion EP. A part of the end portion EP extends in the direction DR and this part may have a first side EP1, a second side EP2, and a third side EP3. The first side EP1 and the third side EP3 may be parallel to the direction DR, and the second side EP2 connects the first side EP1 and the third side EP3 and is not parallel to the direction DR. According to the structural design where the end portion EP of the second conductive element CE2 is step-shaped, the height difference of the film layers can be reduced, thereby reducing the risk of the insulating layer I2 disposed on the second conductive element CE2 breaking.

In a cross-section of the electronic device ED perpendicular to an extending direction of the first control element T1C (for example, the direction Y shown in FIG. 3A), as shown in FIG. 4, the second conductive element CE2 has the endpoint CE2P corresponding to the gap SP, and the first conductive element CE1 has an endpoint CE1P corresponding to the gap SP. In the direction DR parallel to a surface of the substrate SB, a first minimum distance D1 is between the endpoint CE2P of the second conductive element CE2 and the endpoint CE1P of the first conductive element CE1. A second minimum distance D2 is between the endpoint CE1P of the first conductive element CE1 and the insulating layer IG. A ratio of the first minimum distance D1 to the second minimum distance D2 may be greater than or equal to 0.5 and less than or equal to 2 (i.e., 0.5 ≤ D1/D2 ≤ 2). The second conductive element CE2 extends in the direction DR and is overlapped with a part of the second region RB of the first semiconductor SC1 and a part of the gap SP in the direction Z, thereby reducing the resistance of the part of the second region RB and also protecting the second region RB. Furthermore, the second conductive element CE2 may also be electrically connected to other traces in the electronic device ED and have a certain distance from the fifth conductive element CE5. If an extending distance of the second conductive element CE2 (i.e., the first minimum distance D1) is too large and exceeds the above-mentioned ratio range, it may cause a short circuit.

When the first semiconductor SC1 is a metal oxide semiconductor, the material of the first semiconductor SC1 includes, for example (but not limited to), indium gallium zinc oxide (IGZO), amorphous indium gallium zinc oxide (a-IGZO), indium zinc oxide (IZO), amorphous indium-zinc-tin oxide (a-IZTO), zinc tin oxide, indium gallium oxide (IGO), or indium gallium zinc tin oxide (IGZTO), but is not limited thereto. The materials of the first conductive element CE1, the second conductive element CE2, the third conductive element CE3, the fourth conductive element CE4, and the fifth conductive element CE5 may comprise conductive materials such as metal materials or transparent conductive materials.

The electronic device of the present disclosure is not limited to the above-mentioned embodiments. Other embodiments of the electronic device of the present disclosure will be described in detail below. To simplify the description, the same reference numerals are used to denote the same elements, and the differences between different embodiments will be described in detail below, while the same features will not be repeated.

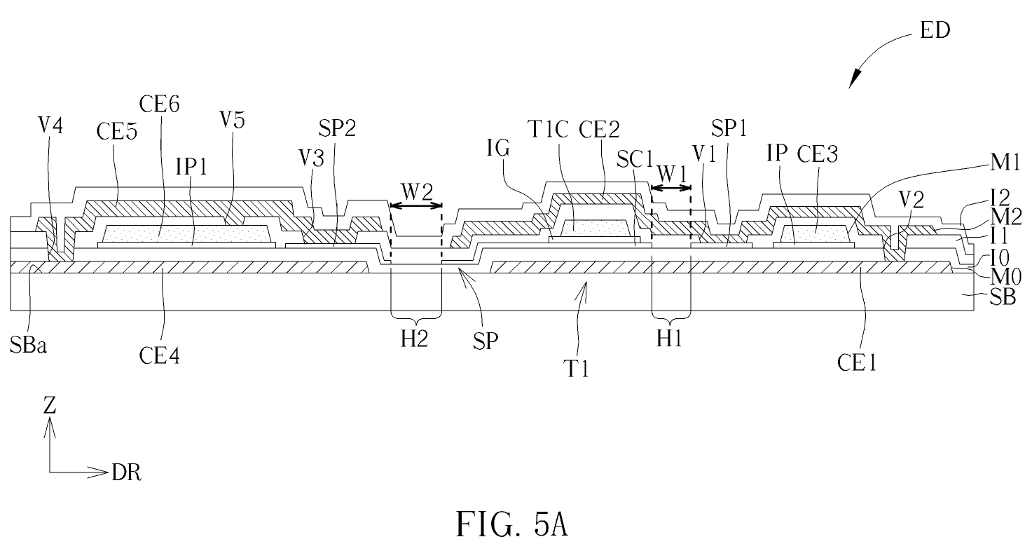

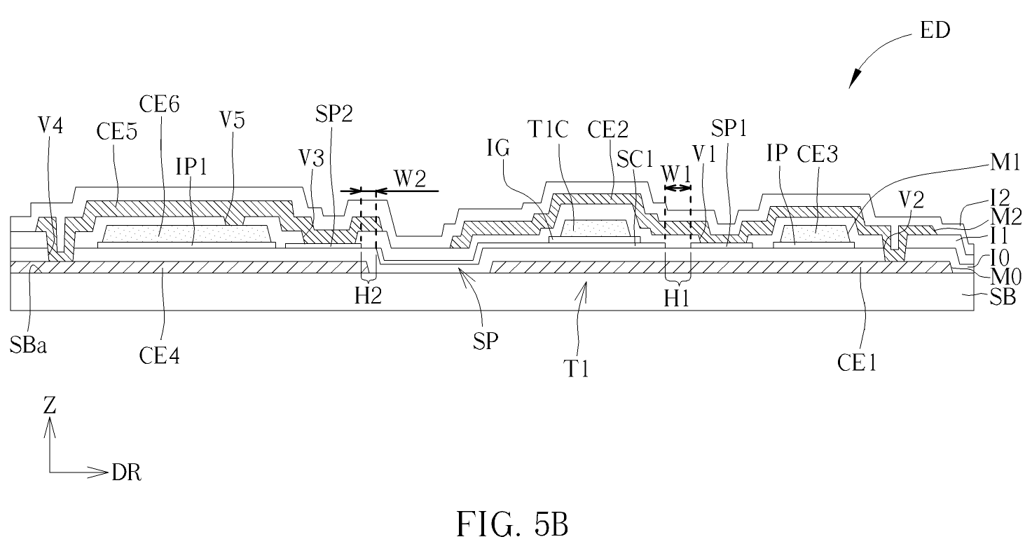

Please refer to FIGS. 5A and 5B. FIG. 5A is a schematic cross-sectional view of a portion of an electronic device according to a second embodiment of the present disclosure. FIG. 5B is a schematic cross-sectional view of a portion of an electronic device according to a third embodiment of the present disclosure. The difference between the electronic devices ED shown in FIGS. 5A and 5B and the first embodiment shown in FIG. 3B is that the first semiconductor SC1 may have a first through-hole H1 adjacent to the via V1, and the first semiconductor SC1 may also have a second through-hole H2 adjacent to the via V3. Specifically, as shown in FIGS. 5A and 5B, the first semiconductor SC1 may have a first portion SP1. The first portion SP1 may directly contact the second conductive element CE2 through the via V1. The first through-hole H1 may be disposed between the first portion SP1 and the portion of the first semiconductor SC1 that is overlapped with the first control element T1C (i.e., the channel region RC shown in FIG. 3B). Furthermore, the first semiconductor SC1 may have a second portion SP2. The second portion SP2 may directly contact the fifth conductive element CE5 through the via V3. The first through-hole H1 may be disposed between the first portion SP1 and the portion of the first semiconductor SC1 that is overlapped with the first control element T1C (i.e., the channel region RC shown in FIG. 3B). By providing the first through-hole H1 and the second through-hole H2, electron shunting can be facilitated to adjust the current, thereby improving the function of the first transistor T1 to control the current.

According to the electronic device ED of the second embodiment shown in FIG. 5A, in the direction Z, the second through-hole H2 may be overlapped with the gap SP, and a projection of the second through-hole H2 on the substrate SB along the direction Z may be completely within the gap SP. In other embodiments, in the direction Z, the second through-hole H2 may be overlapped with the gap SP and a part of the second conductive element CE2, but is not limited thereto. A size of the second through-hole H2 may be larger than a size of the first through-hole H1, but the present disclosure is not limited thereto. In other embodiments, the size of the second through-hole H2 may be equal to or smaller than the size of the first through-hole H1. For example, as shown in FIG. 5A, in the direction DR, a width W2 of the second through-hole H2 may be greater than a width W1 of the first through-hole H1. Alternatively, from a top view, an area of the second through-hole H2 may be larger than an area of the first through-hole H1.

According to the electronic device ED of the third embodiment shown in FIG. 5B, in the direction Z, the second through-hole H2 may be overlapped with the gap SP, a part of the fourth conductive element CE4, and a part of the fifth conductive element CE5, and a projection of the second through-hole H2 on the substrate SB along the direction Z may be partially within the gap SP. A size of the second through-hole H2 may be equal to a size of the first through-hole H1, but the present disclosure is not limited thereto. In other embodiments, the size of the second through-hole H2 may be larger than or smaller than the size of the first through-hole H1. For example, as shown in FIG. 5B, in the direction DR, a width W2 of the second through-hole H2 may be equal to a width W1 of the first through-hole H1. Alternatively, from a top view, an area of the second through-hole H2 may be equal to an area of the first through-hole H1.

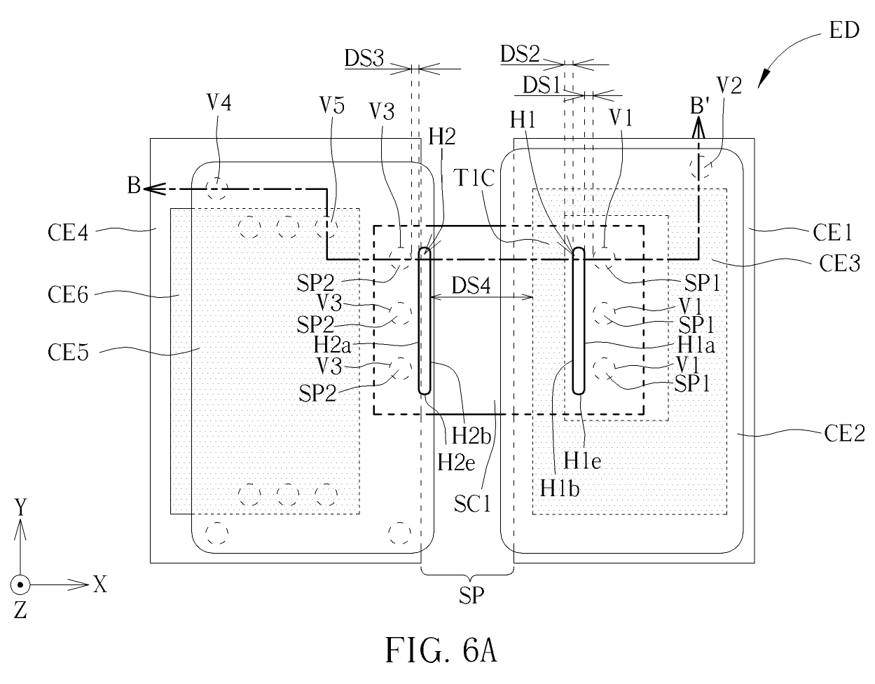

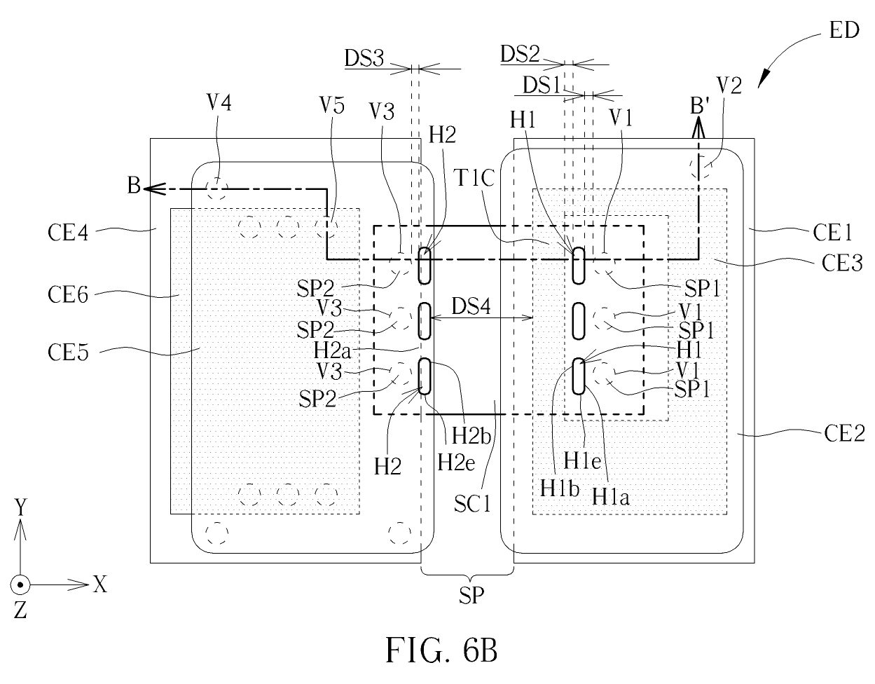

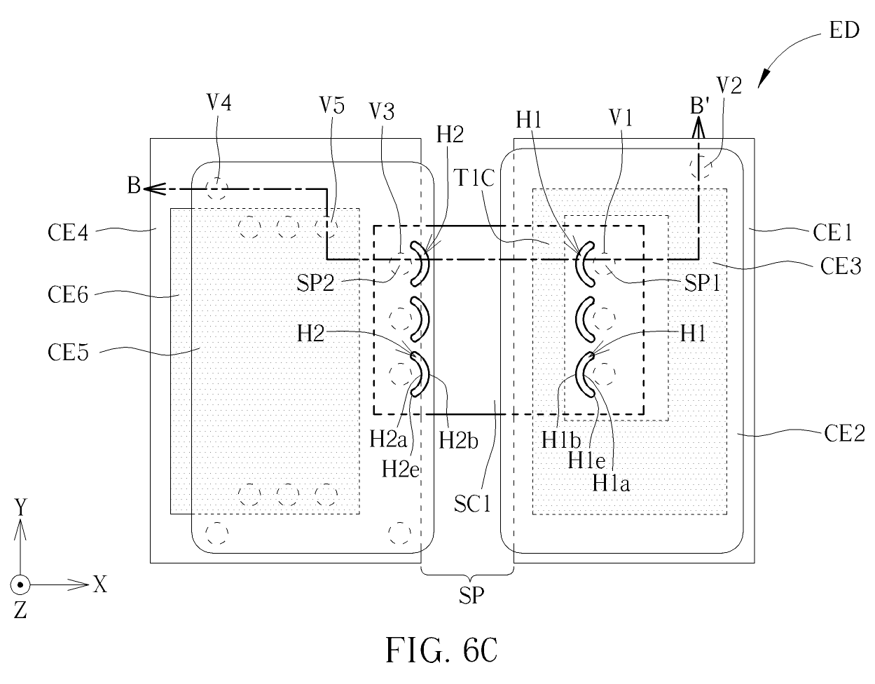

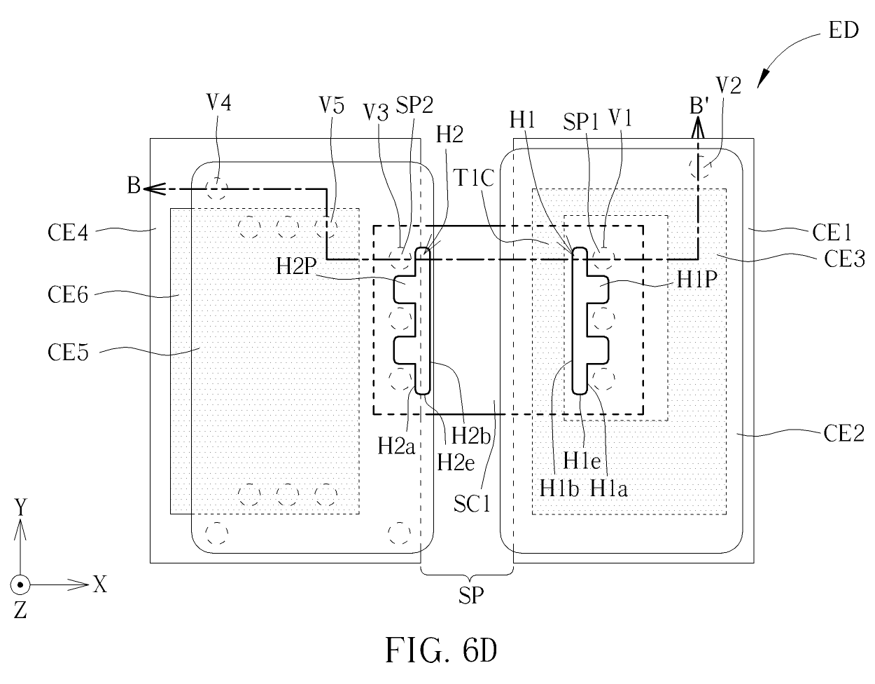

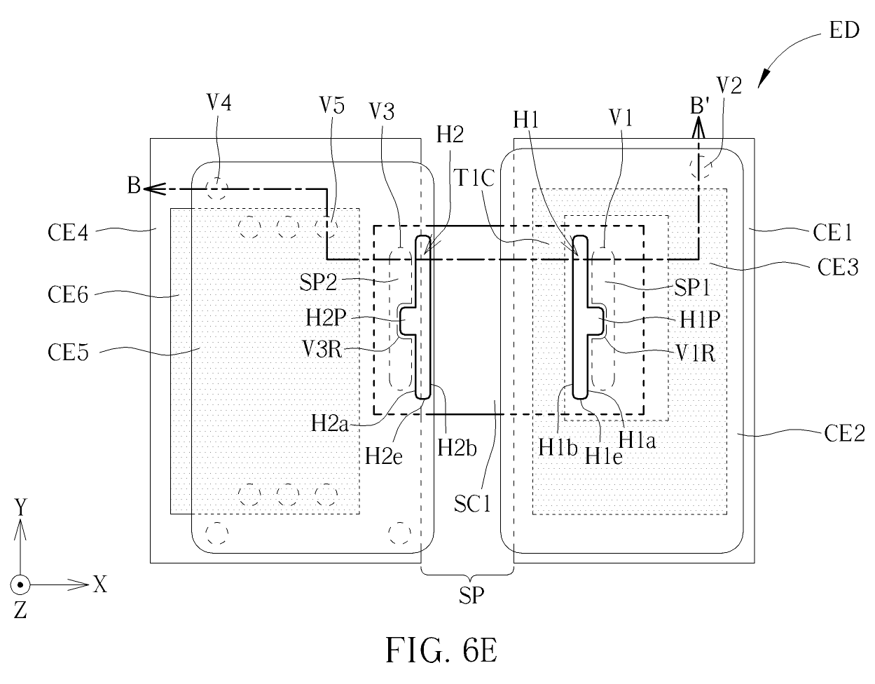

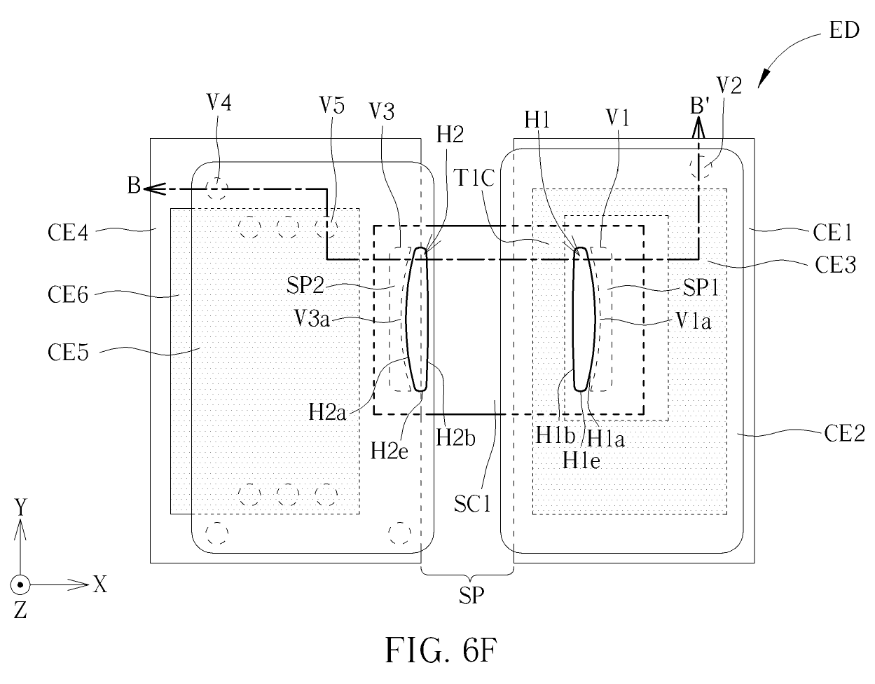

Please refer to FIGS. 6A-6F, in conjunction with FIG. 5B. FIGS. 6A-6F are schematic top views of a portion of an electronic device according to some embodiments of the third embodiment of the present disclosure. The cross-sectional structure corresponding to the section line B-B' in FIGS. 6A-6F can be referred to in FIG. 5B. According to the embodiments shown in FIGS. 6A-6F, in a top view of the electronic device ED, or when viewing the electronic device ED from a direction opposite to the direction Z, the first through-hole H1 has an edge H1e, and at least a portion of the edge H1e may be arc-shaped. For example, the edge H1e of the first through-hole H1 may be arc-shaped at corner positions. The design of the arc-shaped edge H1e can reduce the obstruction to electron migration. As shown in FIGS. 6A-6F, from a top view, in the direction X, the first through-hole H1 may be disposed between the first portion SP1 of the first semiconductor SC1 and the first control element T1C, wherein the first portion SP1 may directly contact the second conductive element CE2 disposed thereon through one or more vias V1. The first through-hole H1 may have a first side H1a and a second side H1b opposite to the first side H1a. In the direction X, the first side H1a is closer to the first portion SP1 than the second side H1b. In the direction X perpendicular to the extending direction Y of the first control element T1C, a first distance DS1 is between the first side H1a and the first portion SP1, and a second distance DS2 is between the second side H1b and the first control element T1C, and the first distance DS1 may be less than the second distance DS2. In the direction X, the first distance DS1 can be obtained by measuring a shortest distance between the first side H1a and the first portion SP1, and the second distance DS2 can be obtained by measuring a shortest distance between the second side H1b and the first control element T1C. According to the structural design where the first distance DS1 is less than the second distance DS2, the first through-hole H1 can be closer to the first portion SP1 where the first semiconductor SC1 and the second conductive element CE2 are in contact, which is beneficial for electron shunting to adjust the current, thereby improving the function of controlling the current. In an embodiment, the first side H1a and the second side H1b of the first through-hole H1 can be distinguished as follows. First, a minimum virtual rectangle encloses the first through-hole H1, and a virtual center of the first through-hole H1 is defined by two diagonal lines. Then, a virtual line passing through the virtual center and parallel to the extending direction of the first control element T1C will intersect the edge H1e of the first through-hole H1 at two points, thereby defining the second side H1b closer to the first control element T1C and the first side H1a closer to the first portion SP1.

According to the embodiments shown in FIGS. 6A-6F, in a top view of the electronic device ED, the second through-hole H2 has an edge H2e, and at least a portion of the edge H2e may be arc-shaped to reduce the obstruction to electron migration. For example, the edge H2e of the second through-hole H2 may be arc-shaped at corner positions. From a top view, in the direction X, the second through-hole H2 may be disposed between the second portion SP2 of the first semiconductor SC1 and the first control element T1C, wherein the second portion SP2 may directly contact the fifth conductive element CE5 disposed thereon through one or more vias V3. The second through-hole H2 may have a third side H2a and a fourth side H2b opposite to the third side H2a. In the direction X, the third side H2a is closer to the second portion SP2 than the fourth side H2b. In the direction X perpendicular to the extending direction Y of the first control element T1C, a third distance DS3 is between the third side H2a and the second portion SP2, and a fourth distance DS4 is between the fourth side H2b and the first control element T1C, and the third distance DS3 may be less than the fourth distance DS4. In the direction X, the third distance DS3 can be obtained by measuring a shortest distance between the third side H2a and the second portion SP2, and the fourth distance DS4 can be obtained by measuring a shortest distance between the fourth side H2b and the first control element T1C. According to the structural design where the third distance DS3 is less than the fourth distance DS4, the second through-hole H2 can be closer to the second portion SP2 where the first semiconductor SC1 and the fifth conductive element CE5 are in contact, which is beneficial for electron shunting to adjust the current, thereby improving the function of controlling the current.

As shown in FIG. 6A, the first through-hole H1 may extend in the direction Y and be adjacent to the first portion SP1 corresponding to a plurality of vias V1. The second through-hole H2 may extend in the direction Y and be adjacent to the second portion SP2 corresponding to a plurality of vias V3. As shown in FIG. 6B, the first semiconductor SC1 may have a plurality of first through-holes H1 and a plurality of second through-holes H2. The plurality of first through-holes H1 and the plurality of vias V1 may be disposed in a one-to-one correspondence and adjacent to each other. The plurality of second through-holes H2 and the plurality of vias V3 may be disposed in a one-to-one correspondence and adjacent to each other, thereby increasing the channels for electron flow, which is more beneficial for current adjustment and/or control. As shown in FIG. 6C, the first semiconductor SC1 may have a plurality of first through-holes H1 and a plurality of second through-holes H2. A top-view shape of the plurality of first through-holes H1 may be arc-shaped and their edge contours may correspond to the edge contours of the vias V1. For example, a shortest distance between any part of the first side H1a of each first through-hole H1 and the adjacent first portion SP1 may be equal. A top-view shape of the plurality of second through-holes H2 may be arc-shaped and their edge contours may correspond to the edge contours of the vias V3. For example, a shortest distance between any part of the third side H2a of each second through-hole H2 and the adjacent second portion SP2 may be equal.

As shown in FIG. 6D, the first through-hole H1 extending along the direction Y may have one or more protruding portions H1P. The protruding portions H1P face toward the first portion SP1 of the first semiconductor SC1. For example, in the direction Y, one protruding portion H1P may be located between two adjacent vias V1. Furthermore, the second through-hole H2 extending along the direction Y may have one or more protruding portions H2P. The protruding portions H2P face toward the second portion SP2 of the first semiconductor SC1. For example, in the direction Y, one protruding portion H2P may be located between two adjacent vias V3. A top-view shape of each protruding portion H1P and each protruding portion H2P may be a rectangle with rounded corners, a semicircle, or a semi-ellipse. According to the above structural design, the length of the electron flow channel, i.e., its path, can be increased, which is more beneficial for current adjustment and/or control.

As shown in FIG. 6E, the first through-hole H1 extending along the direction Y may have a protruding portion H1P, and the via V1 (or the first portion SP1) extending along the direction Y may have a recessed portion V1R. From a top view, a pattern of the protruding portion H1P may correspond to a pattern of the recessed portion V1R and can be embedded in the recessed portion V1R, or in other words, an edge of the protruding portion H1P is adjacent to an edge of the recessed portion V1R. Furthermore, the second through-hole H2 extending along the direction Y may have a protruding portion H2P, and the via V3 (or the second portion SP2) extending along the direction Y may have a recessed portion V3R. From a top view, a pattern of the protruding portion H2P may correspond to a pattern of the recessed portion V3R and be embedded in the recessed portion V3R, or in other words, an edge of the protruding portion H2P is adjacent to an edge of the recessed portion V3R. A top-view shape of the protruding portion H1P and the protruding portion H2P may be a rectangle with rounded corners, a semicircle, or a semi-ellipse. According to the above structural design, the length of the electron flow channel, i.e., its path, can be increased, which is more beneficial for current adjustment and/or control.

As shown in FIG. 6F, a first side H1a of the first through-hole H1 extending along the direction Y may be an arc protruding toward the via V1. A side V1a of the via V1 (or the first portion SP1) adjacent to the first side H1a may be a concave arc. Furthermore, a third side H2a of the second through-hole H2 extending along the direction Y may be an arc protruding toward the via V3. A side V3a of the via V3 (or the second portion SP2) adjacent to the third side H2a may be a concave arc. In some embodiments, a shortest distance between any part of the first side H1a of each first through-hole H1 and the adjacent side V1a may be equal, that is, an extending direction of the first side H1a may be parallel to an extending direction of the side V1a. A shortest distance between any part of the third side H2a of each second through-hole H2 and the adjacent side V3a may be equal, that is, an extending direction of the third side H2a may be parallel to an extending direction of the side V3a. According to the above structural design, the length of the electron flow channel, i.e., its path, can be increased, which is more beneficial for current adjustment and/or control.

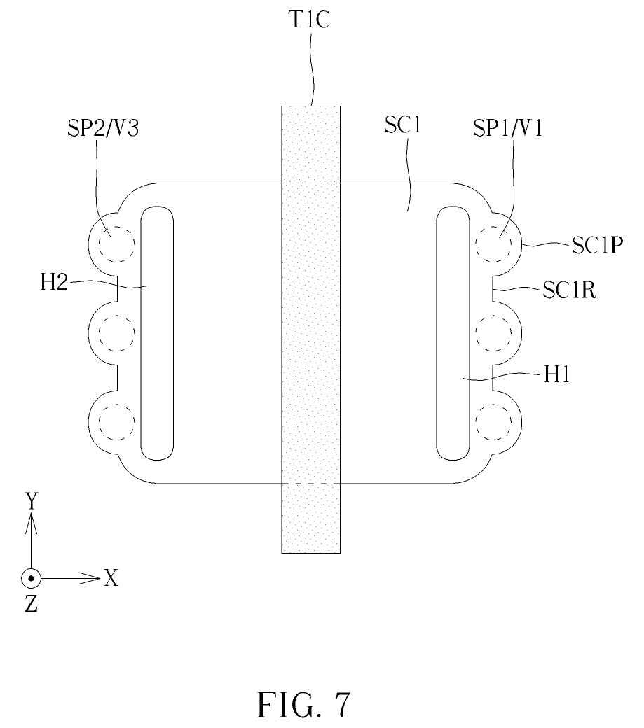

Please refer to FIG. 7, which is a schematic top view of a first semiconductor and a first control element according to an embodiment of the present disclosure. As shown in FIG. 7, from a top view, an edge contour of the first semiconductor SC1 may be conformal to the shapes of the via V1 and the via V3, wherein the shapes of the via V1 and the via V2 correspond to the first portion SP1 and the second portion SP2 of the first semiconductor SC1. For example, the part of the first semiconductor SC1 that is overlapped with the via V1 or the via V3 in the direction Z may have a protruding portion SC1P, and a recessed portion SC1R may be formed between two adjacent protruding portions SC1P. According to the above structural design, the electron flow channel can be made narrower, which is more beneficial for current adjustment and/or control. Furthermore, the first semiconductor SC1 may have a first through-hole H1 and a second through-hole H2, wherein the configurations of the first through-hole H1 and the second through-hole H2 are not limited to the embodiment shown in FIG. 7, and their detailed structures and variations can be referred to in the embodiments shown in FIGS. 6A-6F, which will not be repeated here.

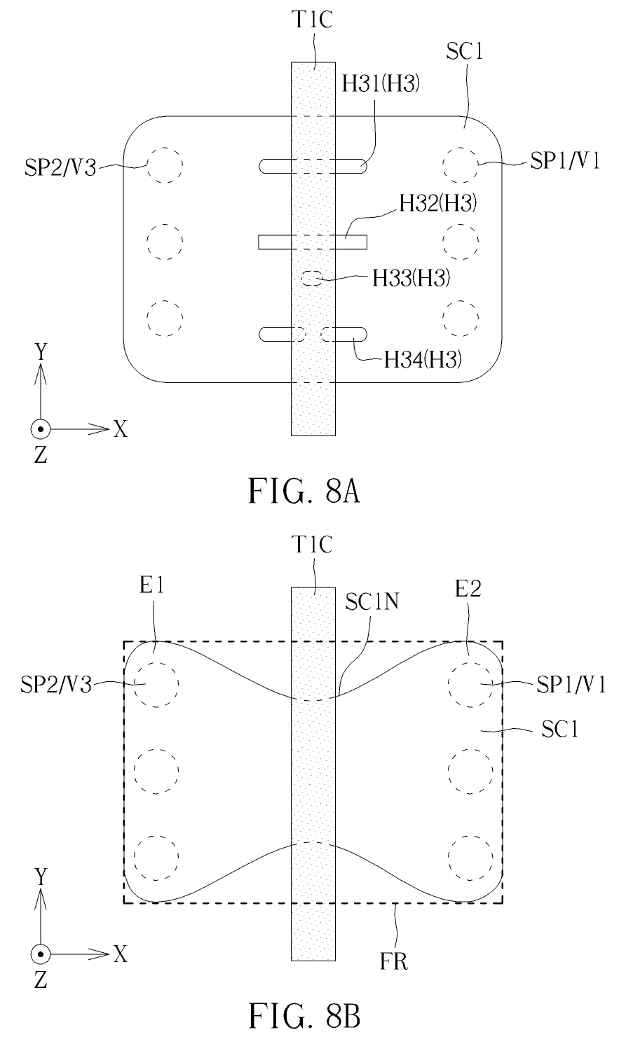

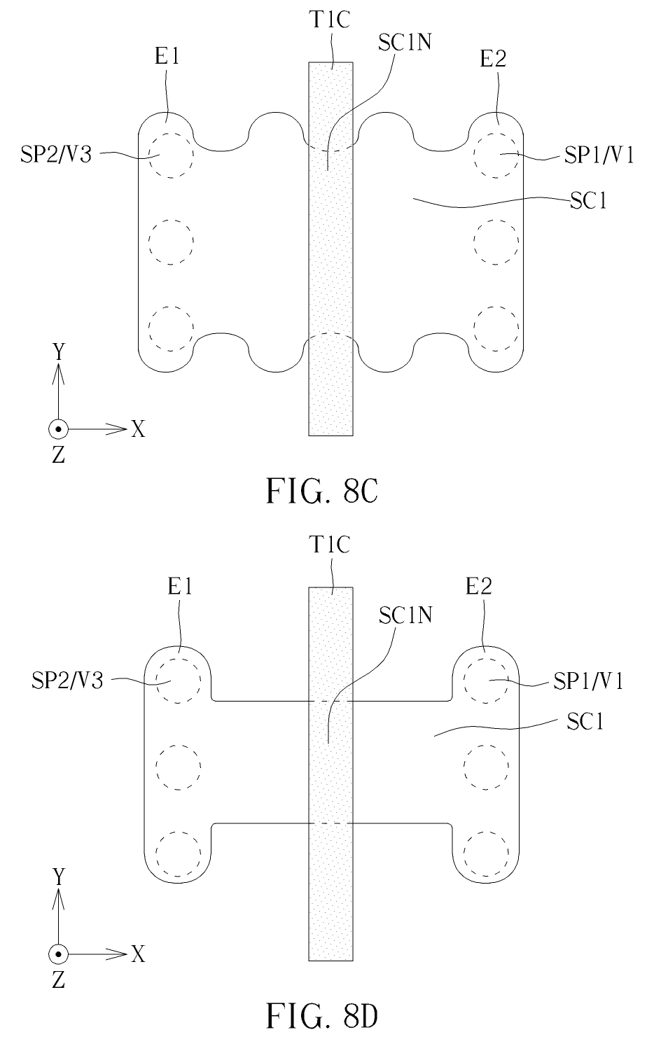

Please refer to FIG. 8A, which is a schematic top view of a first semiconductor and a first control element according to another embodiment of the present disclosure. As shown in FIG. 8A, the first semiconductor SC1 may have one or more through-holes H3 (which can be referred to as first through-holes in this embodiment). In the direction Z, at least a portion of each through-hole H3 may be overlapped with the first control element T1C. Providing the through-holes H3 can make the electron flow channel narrower, which is beneficial for current adjustment and/or control. From a top view, the through-hole H3 may have an edge H3e, and at least a portion of the edge H3e is arc-shaped to reduce the obstruction to electron migration. FIG. 8A shows various configurations of the through-hole H3, namely through-hole H31, through-hole H32, through-hole H33, and through-hole H34. The shape of the through-hole H3 of the first semiconductor SC1 of the present disclosure may be one or more of the configurations shown in FIG. 8A. The shape of the through-hole H31 is an elongated strip extending in the direction X, and a part of the through-hole H31 is overlapped with the first control element T1C in the direction Z. Both ends of the through-hole H31 may be arc-shaped. The shape of the through-hole H32 is an elongated strip extending in the direction X, and a part of the through-hole H32 is overlapped with the first control element T1C in the direction Z. Four corners (or turns) of the through-hole H32 may be arc-shaped. The shape of the through-hole H33 may be circular or elliptical, and the entire through-hole H33 is overlapped with the first control element T1C in the direction Z. The through-holes H34 may be disposed in pairs and spaced on both sides of the first control element T1C. A part of each through-hole H34 is overlapped with the first control element T1C in the direction Z, while another part is not overlapped with it.

Please refer to FIGS. 8B-8D. FIGS. 8B-8D are schematic top views of a first semiconductor and a first control element according to yet other embodiments of the present disclosure. According to the embodiments shown in FIGS. 8B-8D, the first semiconductor SC1 may have a neck portion SC1N. In the direction Z, the neck portion SC1N is overlapped with the first control element T1C. By providing the neck portion SC1N, the electron flow channel can be made narrower, which is beneficial for current adjustment and/or control. Within a minimum virtual rectangular frame FR that can enclose the first semiconductor SC1, an outer edge of the part of the first semiconductor SC1 that is overlapped with the first control element T1C in the direction Z is smaller than a boundary of the virtual rectangular frame FR. The above-mentioned part of the first semiconductor SC1 can be defined as the neck portion SC1N. As shown in FIG. 8B, a width of the first semiconductor SC1 in the direction Y may gradually decrease from two opposite end portions E1 and E2 (the left end portion and the right end portion in FIG. 8B) toward the neck portion SC1N, but is not limited thereto. In other embodiments, the end portions E1 and E2 of the first semiconductor SC1 may be connected to the neck portion SC1N through a plurality of line segments with different slopes. As shown in FIG. 8C, an outer edge of the portion between the end portions E1 and E2 of the first semiconductor SC1 and the neck portion SC1N may have recesses and protrusions, resulting in an uneven shape. As shown in FIG. 8D, a width in the direction Y of the portion between the end portions E1 and E2 of the first semiconductor SC1 and the neck portion SC1N may be equal to a width in the direction Y of the neck portion SC1N, so that a top-view shape of the first semiconductor SC1 may be an H-shape. In some embodiments, the neck portion SC1N in the embodiments shown in FIGS. 8B-8D may also have one or more through-holes H3 as shown in FIG. 8A, but is not limited thereto.

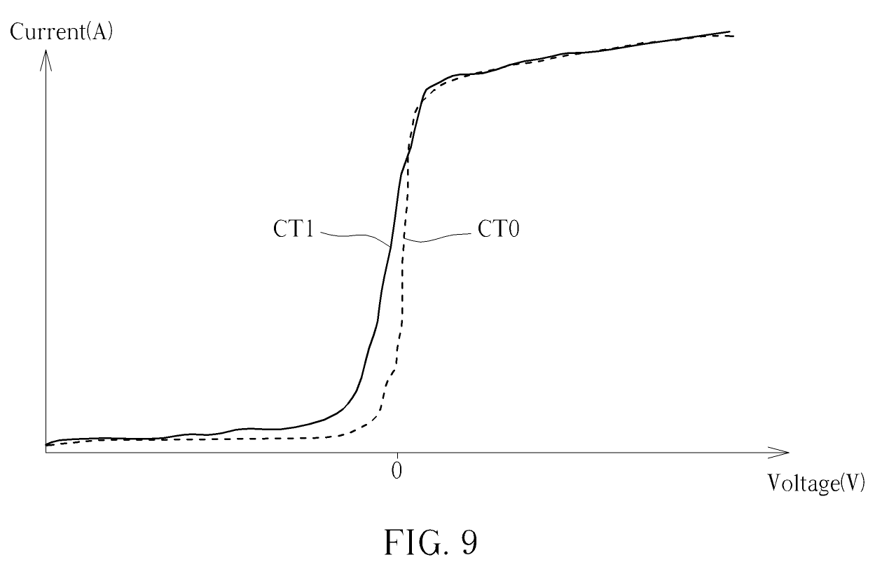

Please refer to FIG. 9, which is a voltage-current characteristic curve diagram of a first transistor of an embodiment of the present disclosure and a comparative example. A curve CT1 shows a relationship between a gate voltage and a drain current of the first transistor T1 of an embodiment of the present disclosure. The first semiconductor SC1 of the first transistor T1 in this embodiment may have through-holes and/or a neck portion, for example, it may correspond to any one or a combination of the first semiconductors SC1 shown in FIGS. 5A-8D. A curve CT0 shows a relationship between a gate voltage and a drain current of a transistor of a comparative example. As shown in FIG. 9, when the gate voltage is 0, the first transistor T1 and the transistor of the comparative example can be turned on and the current rises sharply. At this time, compared to the curve CT0 of the transistor of the comparative example, the curve CT1 of the first transistor T1 of the present disclosure has a gentler current rising slope, which is more beneficial for current control. In other words, when the first semiconductor SC1 has through-holes and/or a neck portion, the current of the first transistor T1 can be adjusted, thereby improving the function of controlling the current. For example, it is beneficial for the control of grayscale levels when the electronic device ED is used for display, to improve the accuracy of grayscale control operations, especially to improve the performance in low grayscale states.

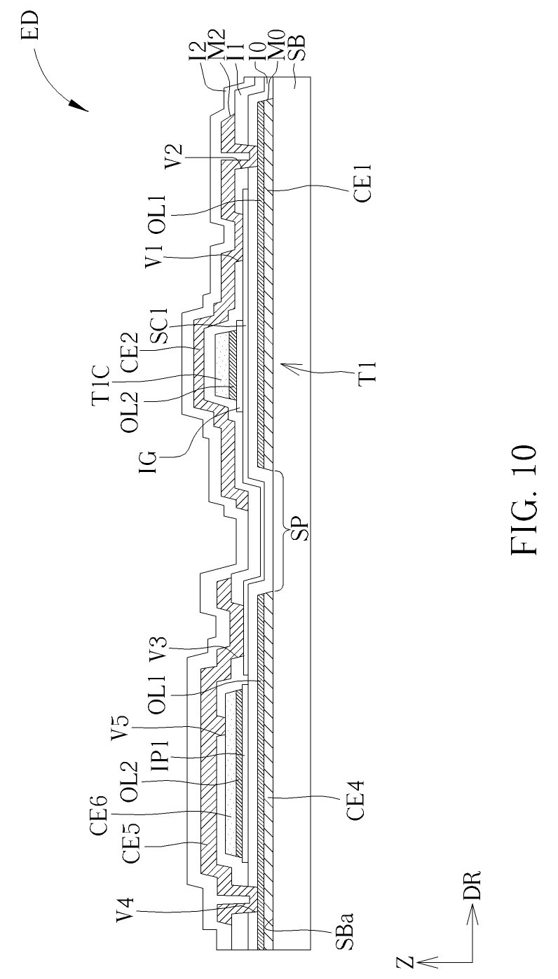

Please refer to FIG. 10, which is a schematic cross-sectional view of a portion of an electronic device according to a fourth embodiment of the present disclosure. The difference between the electronic device ED shown in FIG. 10 and the first embodiment shown in FIG. 3B is that when the first semiconductor SC1 is a metal oxide semiconductor, the electronic device ED may further comprise a first oxide layer OL1 and a second oxide layer OL2 to provide oxygen ions to the first semiconductor SC1, thereby increasing an electron mobility rate in a channel region of the first semiconductor SC1. Specifically, as shown in FIG. 10, in the direction Z, the first oxide layer OL1 may be disposed between the first conductive element CE1 and the insulating layer I0, and the second oxide layer OL2 may be disposed between the insulating layer IG and the first control element T1C. In the cross-section of FIG. 10, the first oxide layer OL1 may completely cover the first conductive element CE1, but the present disclosure is not limited thereto. In other embodiments, in the direction Z, the first oxide layer OL1 may completely correspond to and be overlapped with the first control element T1C or be overlapped with a part of the first control element T1C, that is, the first oxide layer OL1 may only cover a part of the first conductive element CE1. According to the embodiment shown in FIG. 10, the first oxide layer OL1 may also comprise another part disposed between the fourth conductive element CE4 and the insulating layer I0, and the second oxide layer OL2 may also comprise another part disposed between the sixth conductive element CE6 and the insulating portion IP1, but is not limited thereto. The materials of the first oxide layer OL1 and the second oxide layer OL2 may be the same as the material of the first semiconductor SC1, which can be referred to in the foregoing embodiments and will not be repeated here. In some embodiments, in the direction Z, a thickness of the first oxide layer OL1 and a thickness of the second oxide layer OL2 may each be 0.1 to 0.5 times a thickness of the first semiconductor SC1, but is not limited thereto. In some embodiments, the first semiconductor SC1 in the embodiment shown in FIG. 10 may also have a first through-hole H1 and a second through-hole H2 as shown in FIG. 5A or FIG. 5B, but is not limited thereto.

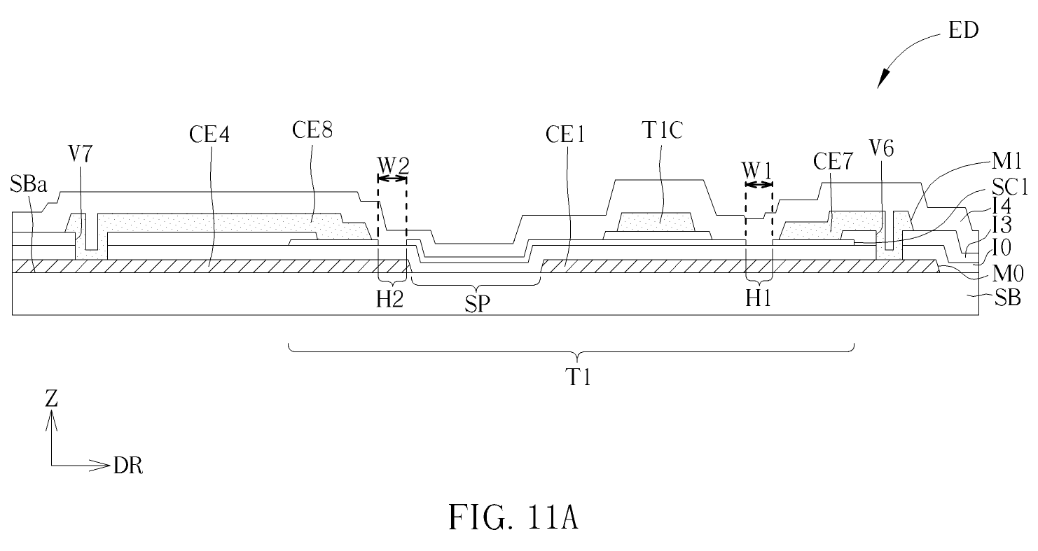

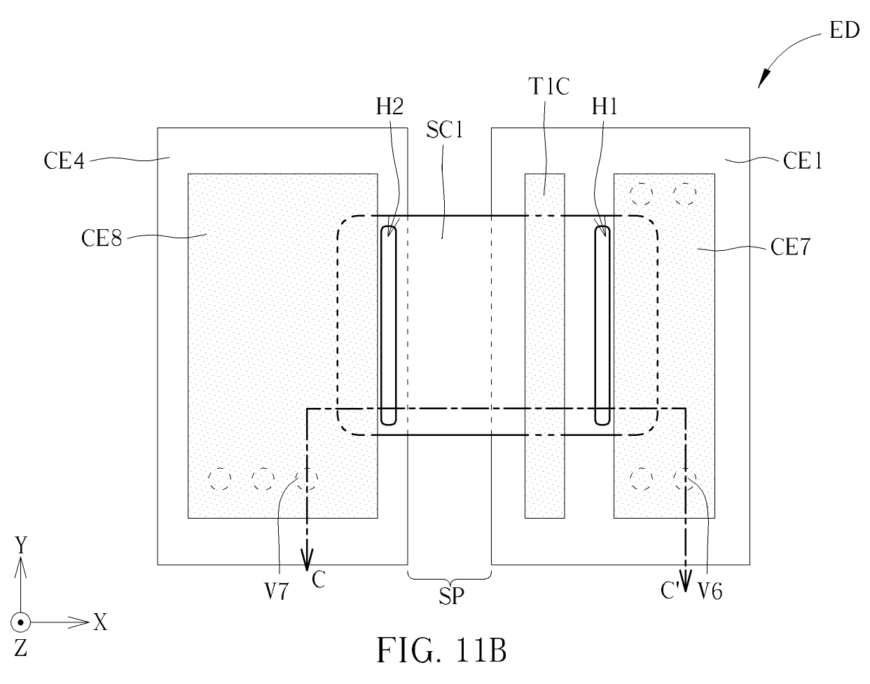

Please refer to FIGS. 11A and 11B. FIG. 11A is a schematic cross-sectional view of a portion of an electronic device according to a fifth embodiment of the present disclosure. FIG. 11B is a schematic top view of a portion of the electronic device according to the fifth embodiment of the present disclosure. For the conciseness of the drawings, FIG. 11B only shows a top view of some elements of the electronic device ED shown in FIG. 11A. The partial cross-sectional structure of the electronic device ED corresponding to the section line C-C' in FIG. 11B can be referred to in FIG. 11A. The difference between the electronic device ED shown in FIGS. 11A and 11B and the first embodiment shown in FIGS. 3A and 3B is that a gate, a drain, and a source of the first transistor T1 can be formed from the same conductive layer M1 to simplify the process and reduce a contact resistance between the drain/source and the first semiconductor SC1, and the first semiconductor SC1 can have a first through-hole H1 and a second through-hole H2 to improve the function of controlling the current. Specifically, according to the embodiment shown in FIGS. 11A and 11B, the electronic device ED may comprise a conductive layer M0 forming a first conductive element CE1 and a fourth conductive element CE4, an insulating layer I0, a first semiconductor SC1, an insulating layer I3, a conductive layer M1 forming a first control element T1C, a seventh conductive element CE7, and an eighth conductive element CE8, and an insulating layer I4, which are sequentially disposed on the upper surface SBa of the substrate SB along the direction Z. In the direction DR, there may be a gap SP between the first conductive element CE1 and the fourth conductive element CE4. The first control element T1C can serve as a gate of the first transistor T1. In the direction Z, a part of the insulating layer I3 can be disposed between the first control element T1C and the first semiconductor SC1 to serve as a gate insulating layer. A part of the seventh conductive element CE7 can be directly disposed on the first semiconductor SC1 and contact and be electrically connected to one end of the first semiconductor SC1 to serve as a drain of the first transistor T1, for example, it can serve as the second terminal T1B (or referred to as the second electrode) shown in FIG. 2A. The seventh conductive element CE7 can be electrically connected to the first conductive element CE1 through a via V6 in the insulating layer I3 and the insulating layer I0. A part of the eighth conductive element CE8 can be directly disposed on the first semiconductor SC1 and contact and be electrically connected to the other end of the first semiconductor SC1 to serve as a source of the first transistor T1, for example, it can serve as the first terminal T1A (or referred to as the first electrode) shown in FIG. 2A. The eighth conductive element CE8 can be electrically connected to the fourth conductive element CE4 through a via V7 in the insulating layer I3 and the insulating layer I0.

As shown in FIGS. 11A and 11B, the first through-hole H1 can be close to the part of the first semiconductor SC1 that contacts the seventh conductive element CE7, and the second through-hole H2 can be close to the part of the first semiconductor SC1 that contacts the seventh conductive element CE7. The configurations of the first through-hole H1 and the second through-hole H2 of the first semiconductor SC1 are not limited to the embodiment shown in FIG. 11B, and they can also be any of the configurations of the first through-hole H1 and the second through-hole H2 shown in FIGS. 6B-6F. By providing the first through-hole H1 and the second through-hole H2, electron shunting can be facilitated to adjust the current, thereby improving the function of controlling the current. According to the embodiment shown in FIGS. 11A and 11B, in the direction Z, the second through-hole H2 may be overlapped with a part of the fourth conductive element CE4 and not be overlapped with the gap SP. A size of the second through-hole H2 may be equal to a size of the first through-hole H1. For example, as shown in FIG. 11A, in the direction DR, a width W2 of the second through-hole H2 may be equal to a width W1 of the first through-hole H1. Alternatively, as shown in FIG. 11B, from a top view, an area of the second through-hole H2 may be equal to an area of the first through-hole H1. However, the present disclosure is not limited to the above. In other embodiments, the size of the second through-hole H2 may be larger than or smaller than the size of the first through-hole H1.

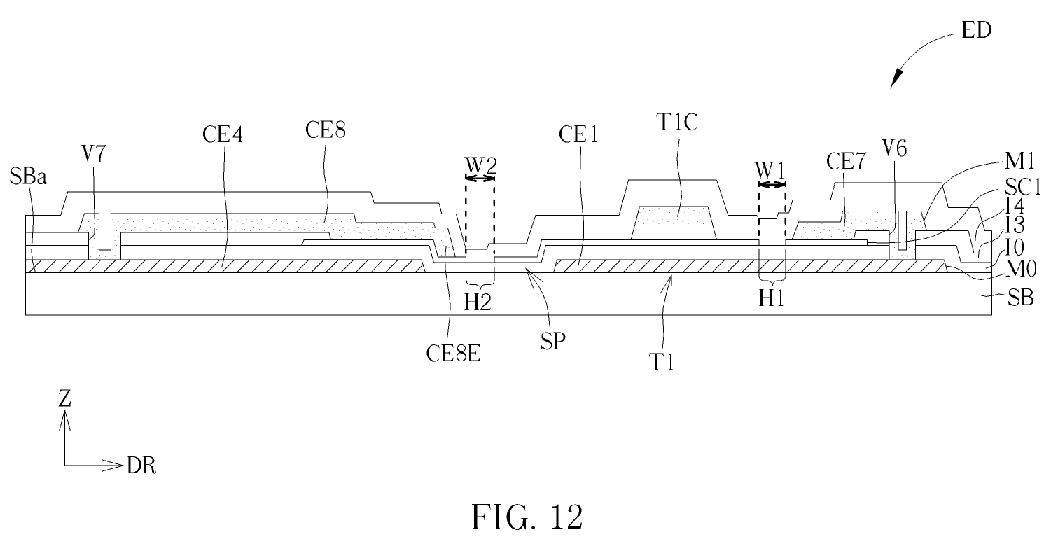

Please refer to FIG. 12, which is a schematic cross-sectional view of a portion of a variation of the electronic device according to the fifth embodiment of the present disclosure. The difference between the electronic device ED shown in FIG. 12 and the fifth embodiment shown in FIG. 11A is that, in the direction Z, the second through-hole H2 may be overlapped with the gap SP between the first conductive element CE1 and the fourth conductive element CE4, and the eighth conductive element CE8 has an end portion CE8E corresponding to the gap SP. As shown in FIG. 12, a projection of the second through-hole H2 on the substrate SB along the direction Z may be completely within the gap SP, that is, in the direction Z, the second through-hole H2 may not be overlapped with the fourth conductive element CE4. In the direction Z, the end portion CE8E of the eighth conductive element CE8 is overlapped with the gap SP, and a shape of the end portion CE8E may be step-shaped, but is not limited thereto.

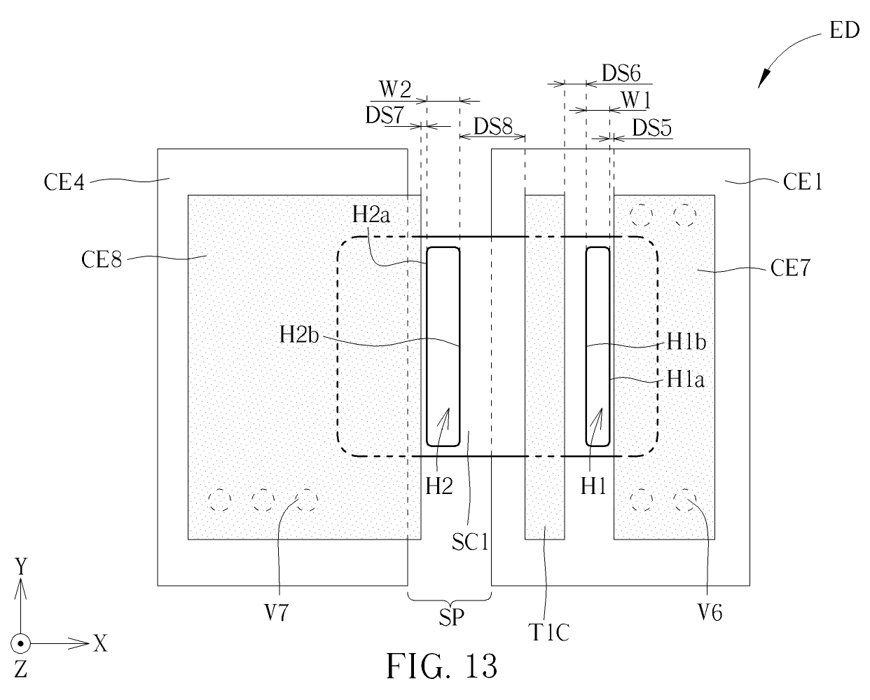

Please refer to FIG. 13, which is a schematic top view of a portion of another variation of the electronic device according to the fifth embodiment of the present disclosure. The difference between the electronic device ED shown in FIG. 13 and the fifth embodiment shown in FIG. 11B is that, in the direction Z, the second through-hole H2 may be overlapped with the gap SP between the first conductive element CE1 and the fourth conductive element CE4, and from a top view, an area of the second through-hole H2 may be larger than an area of the first through-hole H1. According to the embodiment shown in FIG. 13, in the direction X, a width W2 of the second through-hole H2 may be greater than a width W1 of the first through-hole H1. In the top view shown in FIG. 13, the first through-hole H1 may have a first side H1a and a second side H1b opposite to the first side H1a. In the direction X, the first side H1a is closer to the seventh conductive element CE7 than the second side H1b. In the direction X perpendicular to the extending direction Y of the first control element T1C, a fifth distance DS5 is between the first side H1a and the seventh conductive element CE7, and a sixth distance DS6 is between the second side H1b and the first control element T1C, and the fifth distance DS5 may be less than the sixth distance DS6. The second through-hole H2 may have a third side H2a and a fourth side H2b opposite to the third side H2a. In the direction X, the third side H2a is closer to the eighth conductive element CE8 than the fourth side H2b. In the direction X perpendicular to the extending direction Y of the first control element T1C, a seventh distance DS7 is between the third side H2a and the eighth conductive element CE8, and an eighth distance DS8 is between the fourth side H2b and the first control element T1C, and the seventh distance DS7 may be less than the eighth distance DS8. In some embodiments, the eighth distance DS8 may be greater than or equal to the sixth distance DS6, and the seventh distance DS7 may be approximately equal to the fifth distance DS5, wherein the seventh distance DS7 may be, for example, greater than 0 and less than or equal to 2 micrometers (µm).

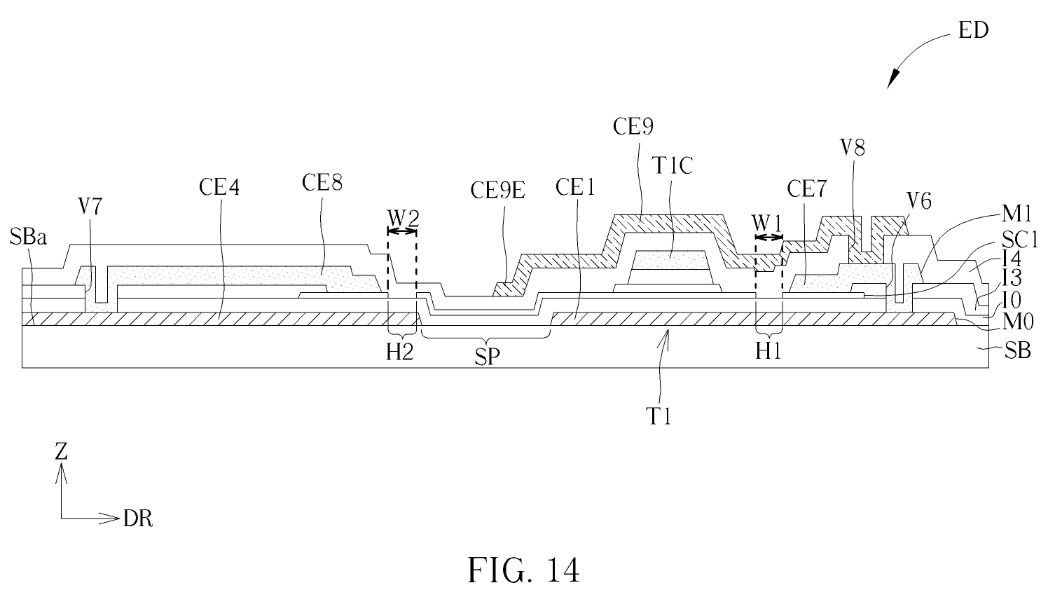

Please refer to FIG. 14, which is a schematic cross-sectional view of a portion of an electronic device according to a sixth embodiment of the present disclosure. The difference between the electronic device ED shown in FIG. 14 and the fifth embodiment shown in FIG. 11A is that the electronic device ED further comprises a ninth conductive element CE9. In the direction Z, the ninth conductive element CE9 is overlapped with the first control element T1C and the first semiconductor SC1, and the ninth conductive element CE9 can be electrically connected to the first conductive element CE1. Specifically, as shown in FIG. 14, the ninth conductive element CE9 can be disposed on the insulating layer I4, and the ninth conductive element CE9 has an end portion CE9E corresponding to the gap SP between the first conductive element CE1 and the fourth conductive element CE4, wherein a shape of the end portion CE9E can be step-shaped. The ninth conductive element CE9 can be electrically connected to the seventh conductive element CE7 through a via V8 in the insulating layer I4, and be electrically connected to the first conductive element CE1 through the via V6. When the first transistor T1 receives a voltage signal, a potential field can be generated between the first conductive element CE1 and the ninth conductive element CE9, thereby reducing the resistance of a local region of the first semiconductor SC1. The working principle can be referred to the potential field generated between the first conductive element CE1 and the second conductive element CE2 in the aforementioned first embodiment, and will not be repeated here. In some embodiments, the ninth conductive element CE9 can be electrically connected to the seventh conductive element CE7 through the via V8 in the insulating layer I4, and the seventh conductive element CE7 is not electrically connected to the first conductive element CE1. The ninth conductive element CE9 can be electrically connected to the first conductive element CE1 through another via (not shown) in the insulating layer I4, the insulating layer I3, and the insulating layer I0, but is not limited thereto.

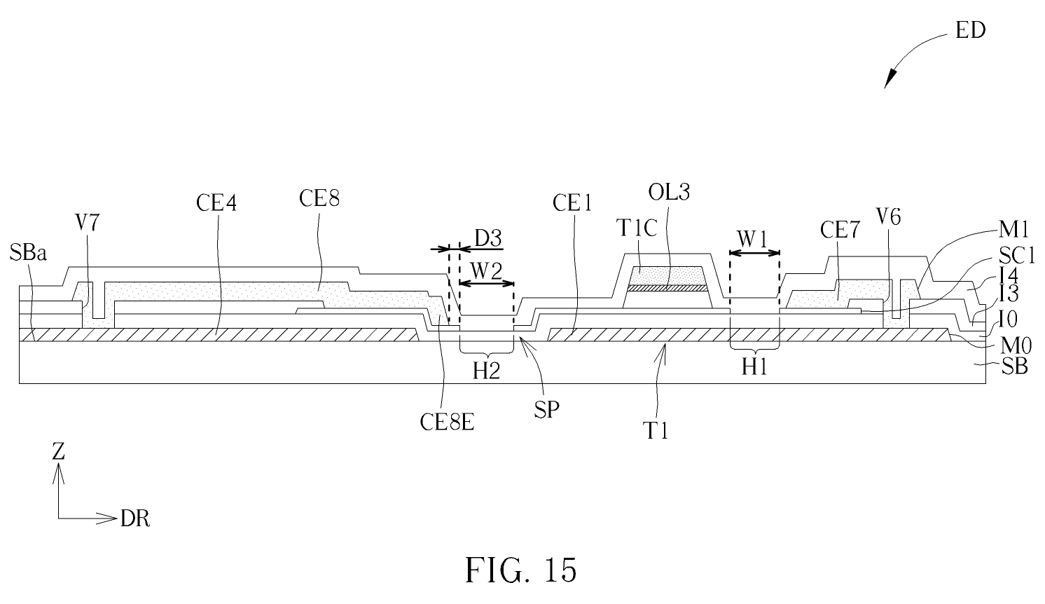

Please refer to FIG. 15, which is a schematic cross-sectional view of a portion of an electronic device according to a seventh embodiment of the present disclosure. The difference between the electronic device ED shown in FIG. 15 and the embodiment shown in FIG. 11B is that when the first semiconductor SC1 is a metal oxide semiconductor, the electronic device ED may further comprise a third oxide layer OL3. In the direction Z, the third oxide layer OL3 may be disposed between the first control element T1C and the insulating layer IG to provide oxygen ions to the first semiconductor SC1, thereby increasing an electron mobility rate in a channel region of the first semiconductor SC1. As shown in FIG. 15, in the direction DR, a third minimum distance D3 is between an edge of the second through-hole H2 of the first semiconductor SC1 and an end portion CE8E of the eighth conductive element CE8, wherein the third minimum distance D3 may be greater than 0 and less than or equal to 2 micrometers. In some embodiments, the electronic device ED may further comprise a fourth oxide layer (not shown). In the direction Z, the fourth oxide layer may be disposed between the first conductive element CE1 and the insulating layer I0, and in the direction Z, the fourth oxide layer may completely correspond to and be overlapped with the first control element T1C or be overlapped with a part of the first control element T1C, that is, the fourth oxide layer may only cover a part of the first conductive element CE1, or the fourth oxide layer may completely cover the first conductive element CE1.

Please refer to FIG. 16A, which is a schematic cross-sectional view of an electronic device having a third transistor according to an embodiment of the present disclosure. According to the embodiment shown in FIG. 16A, and in conjunction with FIGS. 1, 2A, 2B, and 12, the electronic device ED may comprise a third transistor T3 disposed in the peripheral area R2 (as shown in FIG. 16A) and a first transistor T1 disposed in the working area R1 (as shown in FIG. 12), wherein the third transistor T3 may be a transistor in the gate signal driving circuit GD (shown in FIG. 2A). The third transistor T3 may comprise a tenth conductive element CE10, a third control element T3C, a third semiconductor SC3, a first terminal T3A, and a second terminal T3B. In the direction Z, the third semiconductor SC3 may be disposed between the tenth conductive element CE10 and the third control element T3C. The first terminal T3A and the second terminal T3B of the third transistor T3 may be a first electrode and a second electrode of the third transistor T3, respectively, and are electrically connected to opposite ends of the third semiconductor SC3. As shown in FIGS. 2B, 12 and 16A, at least one of the first semiconductor SC1, the second semiconductor SC2, and the third semiconductor SC3 may have at least one through-hole. For example, the first semiconductor SC1 of the first transistor T1 may have a first through-hole H1 and a second through-hole H2, and the third semiconductor SC3 of the third transistor T3 may have one or more through-holes H4. By providing the above-mentioned through-holes, electron shunting can be facilitated to adjust the current, thereby improving the function of controlling the current. In some embodiments, as shown in FIG. 2B, the second semiconductor SC2 of the second transistor T2 may not have a through-hole, but is not limited thereto.

According to the embodiment shown in FIG. 16A, the electronic device ED may comprise a conductive layer M0 forming a tenth conductive element CE10, an insulating layer I0, a third semiconductor SC3, an insulating layer I3, and a conductive layer M1 forming a third control element T3C, a first terminal T3A (or referred to as a first electrode), and a second terminal T3B (or referred to as a second electrode), which are sequentially disposed on the upper surface SBa of the substrate SB along the direction Z. The third control element T3C can serve as a gate of the third transistor T3. In the direction Z, a part of the insulating layer I3 can be disposed between the third control element T3C and the third semiconductor SC3 to serve as a gate insulating layer. A part of the first terminal T3A of the third transistor T3 can be disposed on the third semiconductor SC3 and directly contact one end of the third semiconductor SC3 to serve as a source of the third transistor T3. A part of the second terminal T3B of the third transistor T3 can be disposed on the third semiconductor SC3 and directly contact the other end of the third semiconductor SC3 to serve as a drain of the third transistor T3.

Please refer to FIG. 16B, which is a schematic cross-sectional view of an electronic device having a third transistor according to another embodiment of the present disclosure. According to the embodiment shown in FIG. 16B, and in conjunction with FIGS. 1, 2A, and 15,the electronic device ED may comprise a third transistor T3 disposed in the peripheral area R2 (as shown in FIG. 16B) and a first transistor T1 disposed in the working area R1 (as shown in FIG. 15). The difference between the embodiment shown in FIG. 16B and the embodiment shown in FIG. 16A is that when the third semiconductor SC3 is a metal oxide semiconductor, the electronic device ED may further comprise an oxide layer OL4 disposed between the third control element T3C and the insulating layer I3, and the third semiconductor SC3 may not have a through-hole. In some embodiments, the oxide layer OL4 shown in FIG. 16B and the third oxide layer OL3 shown in FIG. 15 may be formed from the same layer, but is not limited thereto. In an embodiment, the electronic device ED may further comprise an oxide layer OL5 disposed between the tenth conductive element CE10 and the insulating layer I0, and the third semiconductor SC3 may not have a through-hole. In another embodiment, when the third semiconductor SC3 is a metal oxide semiconductor, the electronic device ED may further comprise an oxide layer OL4 disposed between the third control element T3C and the insulating layer I3 and an oxide layer OL5 disposed between the tenth conductive element CE10 and the insulating layer I0, and the third semiconductor SC3 may not have a through-hole.

Please refer to FIG. 16C, which is a schematic cross-sectional view of an electronic device having a third transistor according to yet another embodiment of the present disclosure. According to the embodiment shown in FIG. 16C, and in conjunction with FIGS. 1, 2A, and 10, when the first semiconductor SC1 and the third semiconductor SC3 are metal oxide semiconductors, the electronic device ED may comprise a third transistor T3 disposed in the peripheral area R2 (as shown in FIG. 16C) and a first transistor T1 disposed in the working area R1 (as shown in FIG. 10). The difference between the embodiment shown in FIG. 16C and the embodiment shown in FIG. 16B is that the first terminal T3A (or referred to as a first electrode) and the second terminal T3B (or referred to as a second electrode) of the third transistor T3 are formed from another conductive layer M2, which is different from the conductive layer M1 forming the third control element T3C. Specifically, as shown in FIG. 16C, the electronic device ED may comprise a conductive layer M0 forming a tenth conductive element CE10, an oxide layer OL5, an insulating layer I0, a third semiconductor SC3, an insulating layer IG1, an oxide layer OL4, a conductive layer M1 forming a third control element T3C, an insulating layer I1, a conductive layer M2 forming the first terminal T3A and the second terminal T3B, and an insulating layer I2, which are sequentially disposed on the upper surface SBa of the substrate SB along the direction Z. The insulating layer IG1 can be disposed between the third control element T3C and the third semiconductor SC3 to serve as a gate insulating layer. The first terminal T3A can be electrically connected to one end of the third semiconductor SC3 through a via V9 in the insulating layer I1, and the second terminal T3B can be electrically connected to the other end of the third semiconductor SC3 through a via V10 in the insulating layer I1. In some embodiments, the oxide layer OL5 shown in FIG. 16C and the first oxide layer OL1 shown in FIG. 10 may be formed from the same layer. The oxide layer OL4 shown in FIG. 16C and the second oxide layer OL2 shown in FIG. 10 may be formed from the same layer. The insulating layer IG1 shown in FIG. 16C and the insulating layer IG shown in FIG. 10 may be formed from the same layer, but is not limited thereto.

In summary, according to the electronic device of the embodiments of the present disclosure, through a special stacked design of the first transistor, the resistance of a local region of the first semiconductor can be adjusted, and the first conductive element and the second conductive element can serve as barrier layers to reduce the diffusion of hydrogen ions and oxygen ions into the channel region, thereby improving the driving capability and/or stability of the first transistor. In addition, the first semiconductor can have a first through-hole and a second through-hole, which is beneficial for electron shunting to adjust the current, thereby improving the function of controlling the current.

The above descriptions are only embodiments of the present disclosure and are not intended to limit the present disclosure. For those of ordinary skill in the art, various modifications and changes can be made to the present disclosure. Any modification, equivalent replacement, improvement, etc., made within the spirit and principles of the present disclosure should be included in the protection scope of the present disclosure.

What is claimed is:

1. An electronic device, comprising:
a substrate;
a first transistor disposed on the substrate; and
an electronic unit electrically connected to the first transistor;
wherein the first transistor comprises:
a first conductive element disposed on the substrate;
a first control element disposed on the first conductive element;
a first semiconductor disposed between the first conductive element and the first control element; and
a second conductive element disposed on the first control element and electrically connected to the first semiconductor and the first conductive element, wherein in a top view of the electronic device, the first control element is overlapped with the second conductive element and the first semiconductor.

2. The electronic device of claim 1, further comprising a third conductive element, wherein in a cross-sectional view of the electronic device, the third conductive element is disposed between the second conductive element and the first conductive element, and wherein the third conductive element and the first control element are formed from the same layer.

3. The electronic device of claim 2, wherein in the cross-sectional view of the electronic device, the first semiconductor is not disposed between the third conductive element and the substrate.

4. The electronic device of claim 2, further comprising a fourth conductive element disposed on the substrate and spaced from the first conductive element by a gap, wherein the fourth conductive element and the first conductive element are formed from the same layer, the second conductive element has an end portion corresponding to the gap, and a shape of the end portion is step-shaped.

5. The electronic device of claim 1, further comprising a fourth conductive element and a fifth conductive element, wherein the first semiconductor is disposed between the fourth conductive element and the fifth conductive element and is overlapped with the fourth conductive element and the fifth conductive element, wherein the fourth conductive element and the first conductive element are formed from the same layer, and the fifth conductive element is electrically connected to the first semiconductor and the fourth conductive element.

6. The electronic device of claim 5, further comprising a sixth conductive element disposed between the fourth conductive element and the fifth conductive element, wherein the fifth conductive element is electrically connected to the sixth conductive element.

7. The electronic device of claim 1, wherein the second conductive element directly contacts the first semiconductor and the first conductive element.

8. The electronic device of claim 1, further comprising:
a fourth conductive element, wherein the fourth conductive element and the first conductive element are formed from the same layer and are spaced from each other by a gap; and
a first insulating layer disposed between the first control element and the first semiconductor;
wherein, in a cross-sectional view of the electronic device perpendicular to an extending direction of the first control element, the second conductive element has an endpoint corresponding to the gap, and the first conductive element has an endpoint corresponding to the gap,
wherein in a direction parallel to a surface of the substrate, a first minimum distance is between the endpoint of the second conductive element and the endpoint of the first conductive element,
wherein in the direction, a second minimum distance is between the endpoint of the first conductive element and the first insulating layer, and
wherein a ratio of the first minimum distance to the second minimum distance is greater than or equal to 0.5 and less than or equal to 2.

9. The electronic device of claim 1, wherein the first semiconductor has a first through-hole, and in the top view of the electronic device, the first through-hole has an edge, and at least a portion of the edge is arc-shaped.

10. The electronic device of claim 9, wherein in the top view of the electronic device, at least a portion of the first through-hole is overlapped with the first control element.

11. The electronic device of claim 9, wherein the first semiconductor has a first portion directly contacting the second conductive element, and in the top view of the electronic device, the first through-hole is disposed between the first portion and the first control element.

12. The electronic device of claim 11, wherein the first through-hole has a first side and a second side opposite to the first side, and the first side is closer to the first portion than the second side, wherein in a direction perpendicular to an extending direction of the first control element, a first distance is between the first side and the first portion, a second distance is between the second side and the first control element, and the first distance is less than the second distance.

13. The electronic device of claim 11, further comprising a fifth conductive element disposed on the first semiconductor, wherein the first semiconductor has a second portion and a second through-hole, the second portion directly contacts the fifth conductive element, and in the top view of the electronic device, the second through-hole is disposed between the second portion and the first control element.

14. The electronic device of claim 13, wherein the second through-hole has a third side and a fourth side opposite to the third side, and the third side is closer to the second portion than the fourth side, wherein in a direction perpendicular to an extending direction of the first control element, a third distance is between the third side and the second portion, a fourth distance is between the fourth side and the first control element, and the third distance is less than the fourth distance.

15. The electronic device of claim 11, wherein in the top view of the electronic device, the first through-hole has a protruding portion, and the protruding portion faces toward the first portion of the first semiconductor.

16. The electronic device of claim 1, wherein the first semiconductor has a neck portion, and the neck portion is overlapped with the first control element.

17. The electronic device of claim 1, further comprising a second transistor and a third transistor, wherein the second transistor is electrically connected to the first control element of the first transistor, and the third transistor is electrically connected to a second control element of the second transistor.

18. The electronic device of claim 17, wherein the second transistor comprises a second semiconductor, the third transistor comprises a third semiconductor, and at least one of the first semiconductor, the second semiconductor, and the third semiconductor has at least one through-hole.

19. The electronic device of claim 18, wherein the second semiconductor does not have a through-hole.
